(19) United States
(12) Patent Application Publication
(10) Pub. No.: US 2026/0150397 A1
(43) Pub. Date: May 28, 2026

(54) STACKED DEVICE WITH DIFFERENT CHANNEL EFFECTIVE WIDTHS AND MANUFACTURING METHOD THEREOF

(71) Applicant: TAIWAN SEMICONDUCTOR MANUFACTURING COMPANY, LTD., Hsinchu (TW)

(72) Inventors: Shih-Hao LIN, Hsinchu City (TW); Chien LIU, Hsinchu City (TW); Zi-Yuan WEI, Hsinchu City (TW)

(73) Assignee: TAIWAN SEMICONDUCTOR MANUFACTURING COMPANY, LTD., Hsinchu (TW)

(21) Appl. No.: 18/962,641

(22) Filed: Nov. 27, 2024

(51) Int. Cl. H10D 84/85; H10B 10/00; H10D 30/01; H10D 30/43; H10D 30/67; H10D 62/10; H10D 64/01; H10D 84/01

(52) U.S. Cl. CPC H10D 84/856; H10B 10/125; H10D 30/014; H10D 30/43; H10D 30/6735; H10D 62/121; H10D 64/017; H10D 84/017

(57) ABSTRACT

A device includes a bottom transistor and a top transistor over the bottom transistor to form a complementary FET device. The top transistor includes a first channel layer, a second channel layer, a top gate structure, and top source/drain epitaxial structures. The first channel layer and the second channel layer are at a same level and extend in a first direction. The top gate structure wraps around the first channel layer and the second channel layer. The first channel layer and the second channel layer are arranged in a second direction substantially perpendicular to the first direction. The top source/drain epitaxial structures are connected to the first channel layer and the second channel layer.

### BACKGROUND

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of an integrated circuit structure (or a semiconductor device) in accordance with some embodiments of the present disclosure.

FIGS. 2-11C illustrate perspective views and cross-sectional views of intermediate stages in the formation of an integrated circuit structure (or a semiconductor device) in accordance with some embodiments of the present disclosure.

FIG. 12A is a cross-sectional view taken along line A-A in FIG. 11C.

FIG. 12B is a cross-sectional view taken along line B-B in FIG. 11C.

FIG. 13 is a perspective view of an integrated circuit structure (or a semiconductor device) in accordance with some embodiments of the present disclosure.

FIGS. 14-22C illustrate perspective views and cross-sectional views of intermediate stages in the formation of an integrated circuit structure (or a semiconductor device) in accordance with some embodiments of the present disclosure.

FIG. 23A is a cross-sectional view taken along line A′-A′ in FIG. 22C.

FIG. 23B is a cross-sectional view taken along line B′-B′ in FIG. 22C.

FIGS. 24A-24C are cross-sectional views of an integrated circuit structure (or a semiconductor device) in accordance with some embodiments of the present disclosure.

FIGS. 25A-25C are cross-sectional views of an integrated circuit structure (or a semiconductor device) in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated. One of ordinary skill in the art will appreciate that the dimensions may be varied according to different technology nodes. One of ordinary skill in the art will recognize that the dimensions depend upon the specific device type, technology generation, minimum feature size, and the like. It is intended, therefore, that the term be interpreted in light of the technology being evaluated.

As used herein, the term “etch selectivity” refers to the ratio of the etch rates of two different materials under the same etching conditions. As used herein, the term “p-type” defines a structure, layer, and/or region as being doped with p-type dopants, such as boron. As used herein, the term “n-type” defines a structure, layer, and/or region as being doped with n-type dopants, such as phosphorus. As used herein, the term “conductive” refers to an electrically conductive structure, layer, and/or region. As used herein, source/drain region(s) may refer to a source or a drain, individually or collectively dependent upon the context.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit structures and methods of forming the same. More particularly, some embodiments of the present disclosure are related to stacked GAA devices including a bottom transistor and a top transistor, which has a channel effective width greater than a channel effective width of the bottom transistor. The increasing of the channel effective width of the top transistor improves the device performance and the current crowding issue thereof.

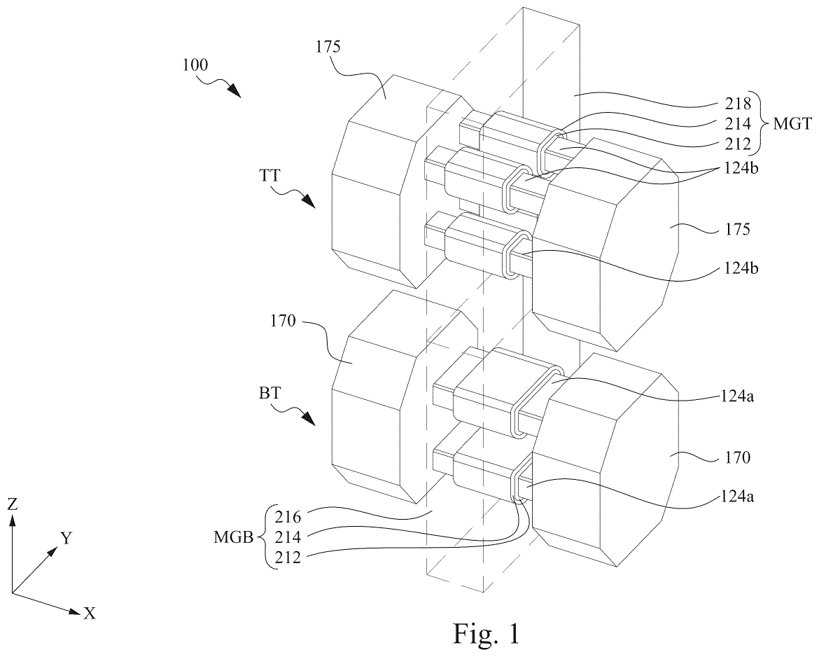

FIG. 1 is a perspective view of an integrated circuit structure (or a semiconductor device) 100 in accordance with some embodiments of the present disclosure. In the present disclosure, a semiconductor device 100 is provided, and its manufacturing method will be disclosed in the following discussion. In addition to the semiconductor device 100, FIG. 1 depicts X-axis, Y-axis, and Z-axis directions. In the semiconductor device 100, a top transistor TT is disposed vertically above a bottom transistor BT. In some embodiments, the bottom transistor BT and the top transistor TT each may be a field effect transistor (FET) and may both include gate-all-around (GAA) configuration, and thus the bottom transistor BT and the top transistor TT can also be referred to as GAA FETs. The bottom transistor BT includes channel structures (or channel layers) 124a vertically stacked one above another, a bottom gate structure MGB wrapping around each of the channel structures 124a, and bottom source/drain epitaxial structures 170 on opposite ends of each of the channel structures 124a. Similarly, the top transistor TT includes channel structures (or channel layers) 124b vertically stacked one above another, a top gate structure MGT wrapping around each of the channel structures 124b, and top source/drain epitaxial structures 175 on opposite ends of each of the channel structures 124b.

In FIG. 1, the channel structures 124a are arranged in a stacking direction (Z-axis in this case). On the other hand, the channel structures 124b not only are arranged in the stacking direction, but are also arranged in a second direction (Y-axis in this case) substantially perpendicular to a first direction (X-axis in this case) where the channel structures 124a and 124b extending. In the embodiments shown in FIG. 1, the channel structures 124b are arranged as a 2 by 2 matrix. In some other embodiment, however, the channel structures 124b can be arranged as an n by m matrix, where n and m are integers greater than 1. Stated another way, a number of the channel structures 124b (e.g., 2 in this case) arranged in the second direction is greater than a number of the channel structures 124a (e.g., 1 in this case) arranged in the second direction. Therefore, a contact area (and thus the channel effective width) between the top gate structure MGT and the channel structures 124b is greater than a contact area (and thus the channel effective width) between the bottom gate structure MGB and the channel structures 124a. The channel effective width is proportional to a perimeter of the channel layers (e.g., the channel structures 124a and 124b). Such configuration improves the device performance and less current crowding.

The bottom gate structure MGB may include interfacial layers 212, high-k gate dielectric layers 214, and a work function metal layer 216. Similarly, the top gate structure MGT may include the interfacial layers 212, the high-k gate dielectric layers 214, and a work function metal layer 218. In some embodiments, the bottom transistor BT has a first conductivity type (e.g., p-type) and the top transistor TT has a second conductivity type (e.g., n-type) different from the first conductivity type. In some embodiments, the bottom transistor BT can be referred to as a P-FET, and the top transistor TT can be referred to as an N-FET.

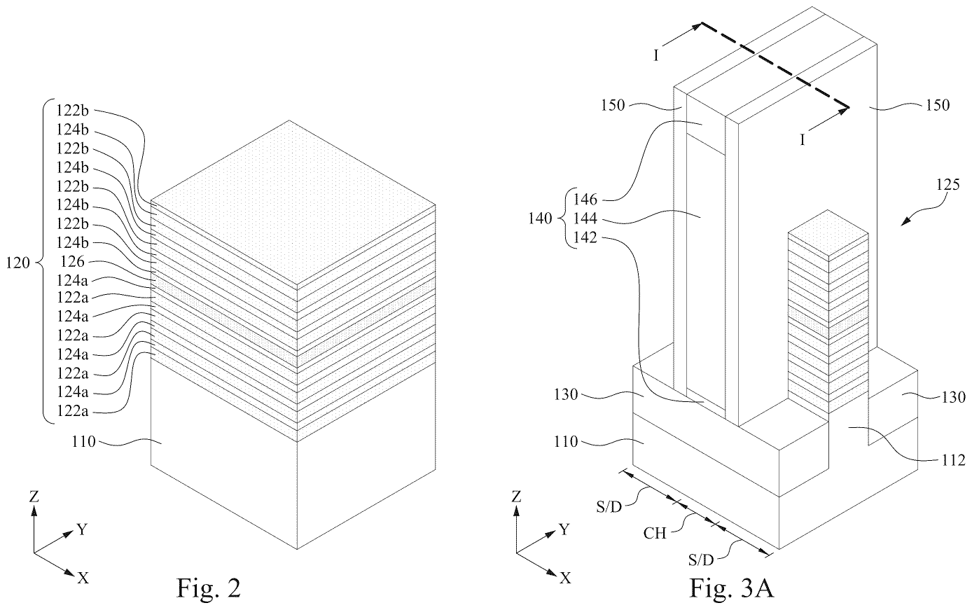

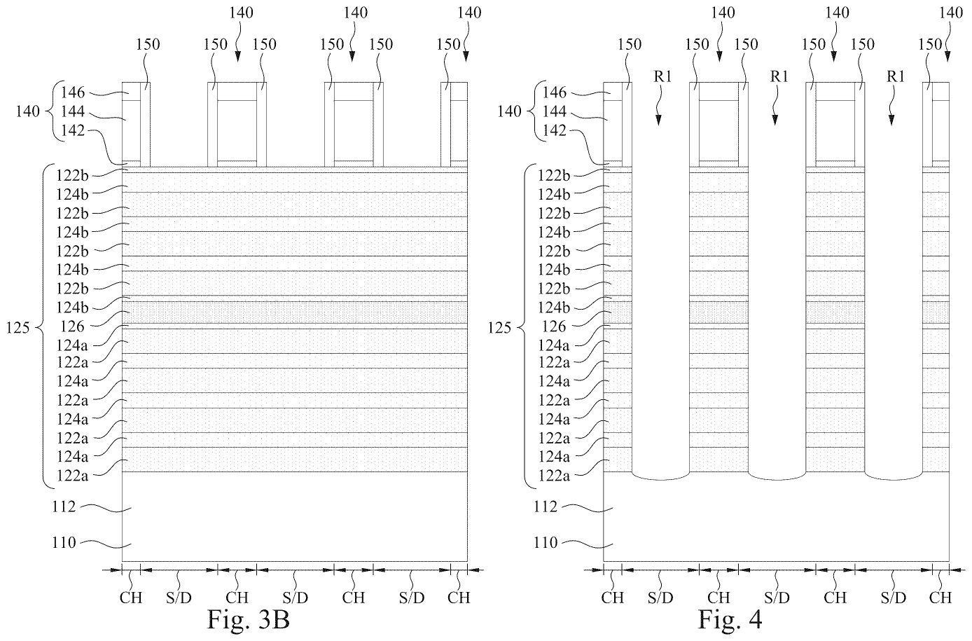

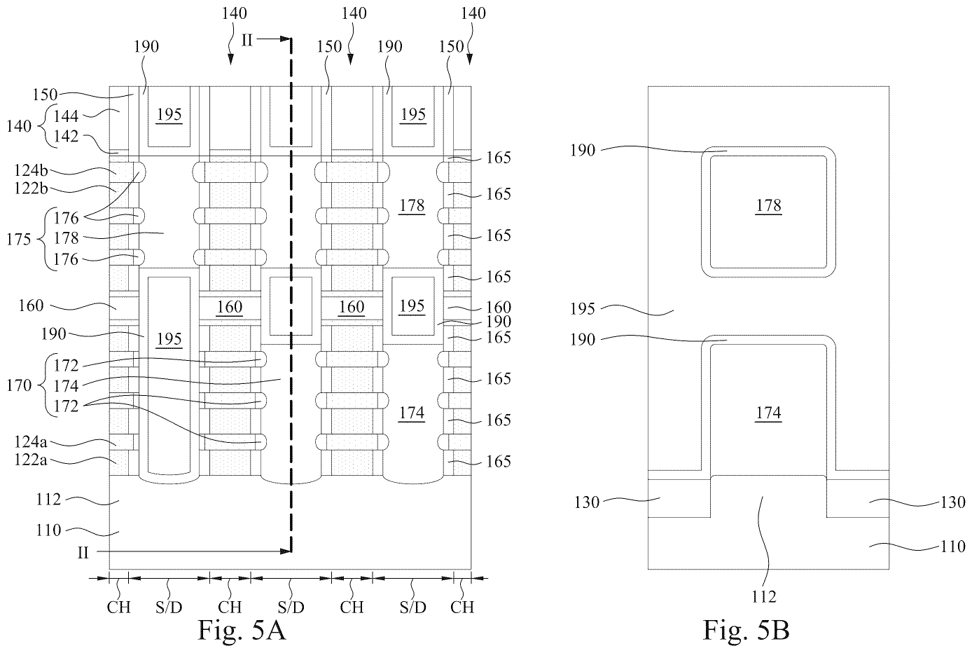

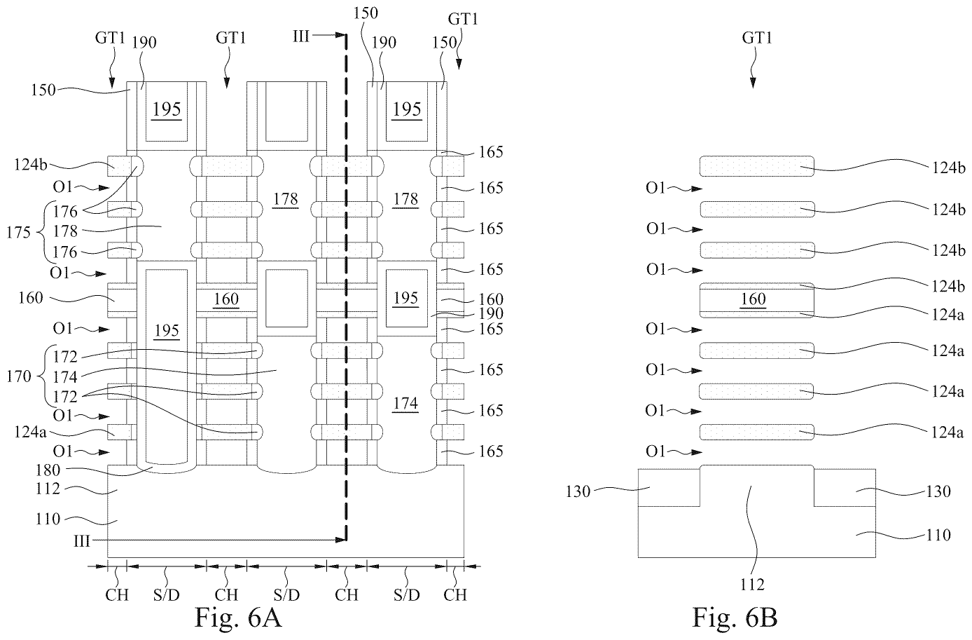

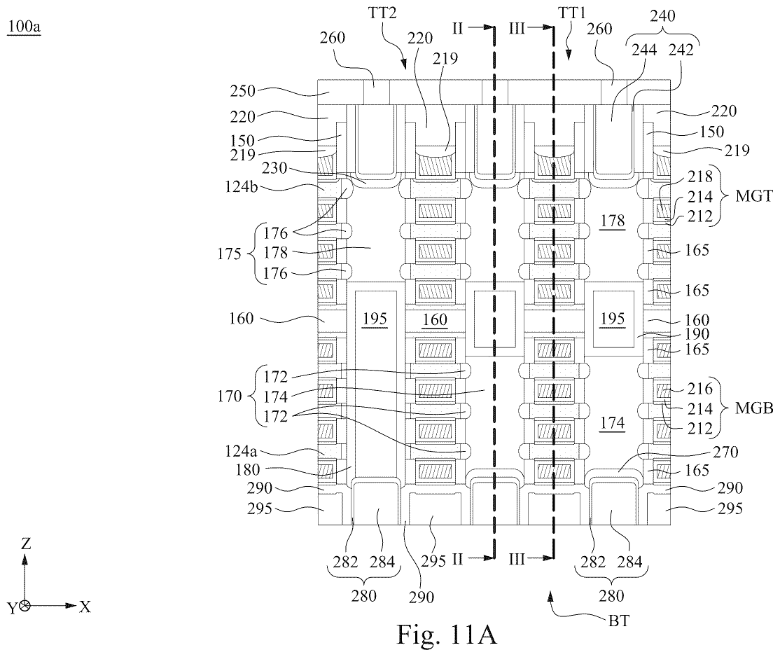

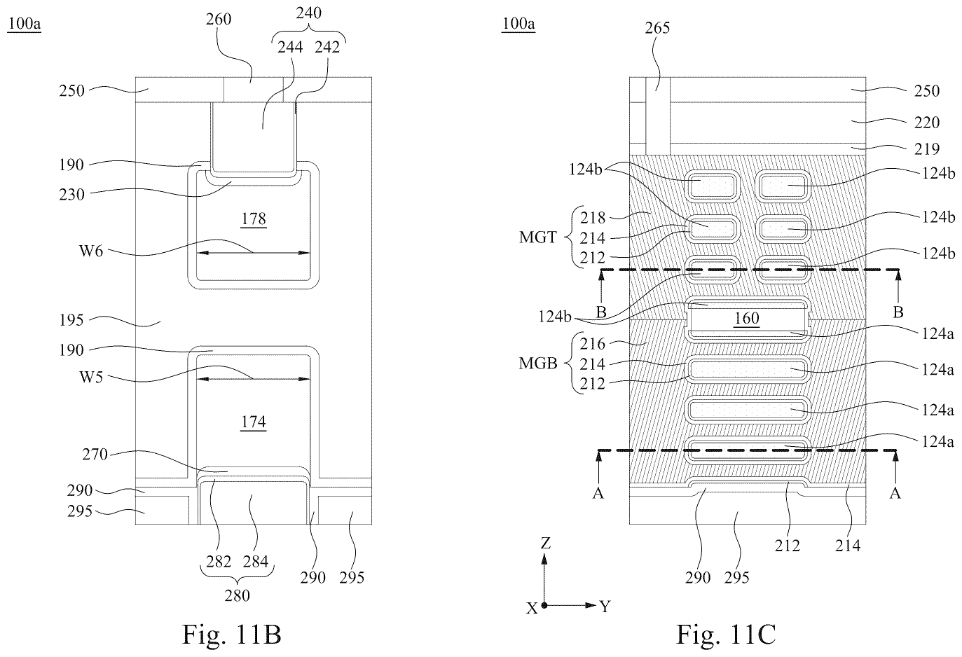

FIGS. 2-11C illustrate perspective views and cross-sectional views of intermediate stages in the formation of an integrated circuit structure (or a semiconductor device) 100a in accordance with some embodiments of the present disclosure. In some embodiments, the semiconductor device 100a in FIGS. 11A-11C is a complementary FET (CFET) device. In addition to the semiconductor device 100a, FIGS. 2, 3A, 11A, and 11C depict X-axis, Y-axis, and Z-axis directions. FIGS. 3B, 4, 5A, 6A, 7A, 8A, 9A, 10A, and 11A are cross-sectional views of some embodiments of the semiconductor device 100a at intermediate stages along a first cut (e.g., cut I-I in FIG. 3A). FIGS. 5B, 10B, and 11B are cross-sectional views of some embodiments of the semiconductor device 100a at intermediate stages along a second cut (e.g., cut II-II in FIGS. 5A, 10A, and 11A). FIGS. 6B, 7B, 8B, 9B, 10C, and 11C are cross-sectional views of some embodiments of the semiconductor device 100a at intermediate stages along a third cut (e.g., cut III-III in FIGS. 6A, 7A, 8A, 9A, 10A, and 11A). The formed devices include a p-type transistor (such as p-type GAA FET) and an n-type transistor (such as an n-type GAA FET) in accordance with some exemplary embodiments. Throughout the various views and illustrative embodiments, like reference numbers are used to designate like elements. It is understood that additional operations can be provided before, during, and after the processes shown by FIGS. 2-11C, and some of the operations described below can be replaced or eliminated, for additional embodiments of the method. The order of the operations/processes may be interchangeable.

Referring to FIG. 2, a semiconductor stack 120 is formed over a substrate 110. In some embodiments, the substrate 110 may include silicon (Si). Alternatively, the substrate 110 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or combinations thereof) or other appropriate semiconductor materials. In some embodiments, the substrate 110 may include a semiconductor-on-insulator (SOI) structure such as a buried dielectric layer. Also alternatively, the substrate 110 may include a buried dielectric layer such as a buried oxide (BOX) layer, such as that formed by a method referred to as separation by implantation of oxygen (SIMOX) technology, wafer bonding, SEG, or another appropriate method.

The semiconductor stack 120 includes semiconductor layers 122a and 122b of a first composition interposed by semiconductor layers 124a and 124b of a second composition arranged in a stacking direction (Z-axis in this case). The semiconductor stack 120 further includes a semiconductor layer 126 between the topmost semiconductor layer 124a and the bottommost semiconductor layer 124b of a third composition. The first, second, and third compositions are different. In some embodiments, the semiconductor layers 122a, 122b, and 126 are SiGe and the semiconductor layers 124a and 124b are silicon (Si). Further, the germanium concentration of the semiconductor layer 126 is higher than the germanium concentration of the semiconductor layer 122a and 122b. However, other embodiments are possible including those that provide for a first composition, a second composition, and a third composition having different etch selectivity.

The semiconductor layers 124a and 124b or portions thereof may form nanostructure channel(s) of the nanostructure transistor. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. For example, the nanostructures are nanosheets, nanowires, nanoslabs, or nanorings, depending on their geometry. The use of the semiconductor layers 124a and 124b to define a channel or channels of a device is further discussed below.

In FIG. 2, the semiconductor layers 124b are disposed above the semiconductor layers 124a. It is noted that four layers of the semiconductor layers 124a and four layers of the semiconductor layers 124b are arranged as illustrated in FIG. 2, which is for illustrative purposes only and not intended to be limiting beyond what is specifically recited in the claims. It can be appreciated that any number of semiconductor layers can be formed in the semiconductor stack 120; the number of layers depending on the desired number of channels regions for the transistor. In some embodiments, the number of each of the semiconductor layers 124a and 124b is between 2 and 10.

As described in more detail below, the semiconductor layers 124a and 124b may serve as channel region(s) for a subsequently-formed semiconductor device and the thickness is chosen based on device performance considerations. The semiconductor layers 122a and 122b in channel region(s) may eventually be removed and serve to define a vertical distance between adjacent channel region(s) for a subsequently-formed multi-gate device and the thickness is chosen based on device performance considerations. Accordingly, the semiconductor layers 122a and 122b may also be referred to as sacrificial layers, and the semiconductor layers 124a and 124b may also be referred to as channel layers.

By way of example, epitaxial growth of the layers of the semiconductor stack 120 may be performed by a molecular beam epitaxy (MBE) process, a metalorganic chemical vapor deposition (MOCVD) process, and/or other suitable epitaxial growth processes. In some embodiments, the epitaxially grown layers such as, the semiconductor layers 124a and 124b include the same material as the substrate 110. In some embodiments, the semiconductor layers 122a, 122b, 124a, 124b, and 126 include a different material than the substrate 110. As stated above, in at least some examples, the semiconductor layers 122a, 122b, and 126 include an epitaxially grown silicon germanium (SiGe) layer and the semiconductor layers 124a and 124b include an epitaxially grown silicon (Si) layer. Alternatively, in some embodiments, either of the semiconductor layers 122a, 122b, 124a, 124b, and 126 may include other materials such as germanium, tin, a compound semiconductor such as silicon carbide, gallium arsenide, gallium phosphide, indium phosphide, indium arsenide, and/or indium antimonide, an alloy semiconductor such as SiGe, GeSn, GaAsP, AlInAs, AlGaAs, InGaAs, GaInP, and/or GaInAsP, III-V, or combinations thereof. As discussed, the materials of the semiconductor layers 122a, 122b, 124a, 124b, and 126 may be chosen based on providing differing oxidation and/or etching selectivity properties.

Reference is made to FIGS. 3A and 3B, where FIG. 3B is a cross-sectional view taken along line I-I of FIG. 3A. At least one fin structure 125 extending from the substrate 110 are formed. In various embodiments, the fin structure 125 includes portions of each of the semiconductor layers of the semiconductor stack 120 including the semiconductor layers 122a, 122b, 124a, 124b, and 126 over a base portion 112 formed from the substrate 110. The fin structure 125 may be fabricated using suitable processes including double-patterning or multi-patterning processes.

For example, a hard mask (HM) layer is formed over the semiconductor stack 120 prior to forming the fin structure 125. The fin structure 125 may subsequently be fabricated using suitable processes including photolithography and etch processes. The photolithography process may include forming a photoresist layer (not shown) over the HM layer, exposing the photoresist to a pattern, performing post-exposure bake processes, and developing the resist to form a patterned mask including the resist. In some embodiments, patterning the resist to form the patterned mask element may be performed using an electron beam (e-beam) lithography process or an extreme ultraviolet (EUV) lithography process using light in EUV region, having a wavelength of, for example, about 1-200 nm. The patterned mask may then be used to protect regions of the substrate 110, and layers formed thereupon, while an etch process forms trenches in unprotected regions through the HM layer, through the semiconductor stack 120, and into the substrate 110, thereby leaving the fin structure 125. The trenches may be etched using a dry etch (e.g., reactive ion etching), a wet etch, and/or combination thereof. Numerous other embodiments of methods to form the fins on the substrate may also be used including, for example, defining the fin region (e.g., by mask or isolation regions) and epitaxially growing the semiconductor stack 120 in the form of the fin structure 125.

Next, isolation structures 130 are formed to surround the fin structure 125. The isolation structures 130 may include a liner oxide (not shown). The liner oxide may be formed of a thermal oxide formed through a thermal oxidation of a surface layer of the substrate 110. The liner oxide may also be a deposited silicon oxide layer formed using, for example, Atomic Layer Deposition (ALD), High-Density Plasma Chemical Vapor Deposition (HDPCVD), or Chemical Vapor Deposition (CVD). The isolation structures 130 may also include a dielectric material over the liner oxide, and the dielectric material may be formed using flowable chemical vapor deposition (FCVD), spin-on coating, or the like.

The isolation structures 130 are then planarized, such that the HM layer is removed, and the top surfaces of the fin structure 125 are exposed. Subsequently, the isolation structures 130 are recessed, so that the top portions of the fin structure 125 protrude higher than the top surfaces of the neighboring isolation structures 130. The etching may be performed using a dry etching process, wherein NH₃ and NF₃ are used as the etching gases. In accordance with alternative embodiments of the present disclosure, the recessing of the isolation structures 130 is performed using a wet etch process. The etching chemical may include diluted HF, for example.

At least one dummy gate structure 140 is formed over the substrate 110 and across the fin structure 125. It is noted that in the first cut (line I-I), four dummy gate structures 140 are illustrated in FIG. 3B to clearly show the detail of the semiconductor device 100a. The portions of the fin structure 125 underlying the dummy gate structures 140 may be referred to as the channel regions CH. The dummy gate structures 140 may also define source/drain regions S/D of the fin structure 125, for example, the regions of the fin structure 125 adjacent and on opposite sides of the channel regions CH.

Dummy gate formation operation forms a dummy gate dielectric layer, a dummy gate electrode layer and a hard mask which may include multiple layers (e.g., a nitride layer and an oxide layer) over the dummy gate electrode layer. The hard mask is then patterned, followed by patterning the dummy gate electrode layer by using the patterned hard mask as an etch mask. The etch process may include a wet etch, a dry etch, and/or combinations thereof. As such, dummy gate structures 140 each including a dummy gate dielectric layer 142, a dummy gate electrode layer 144 and a hard mask 146 (e.g., a nitride layer and an oxide layer) are formed.

After the formation of the dummy gate structures 140 is completed, gate spacers 150 are formed on opposite sidewalls of the dummy gate structures 140. For example, a spacer material layer is deposited on the substrate 110. The spacer material layer may be a conformal layer that is subsequently etched back to form gate sidewall spacers. In the illustrated embodiments, a spacer material layer is disposed conformally on top and sidewalls of the dummy gate structures 140. The spacer material layer may include a dielectric material such as silicon oxide, silicon nitride, silicon carbide, silicon oxynitride, SiCN films, silicon oxycarbide, SiOCN films, and/or combinations thereof. In some embodiments, the spacer material layer includes multiple layers, such as a first spacer layer and a second spacer layer formed over the first spacer layer. By way of example, the spacer material layer may be formed by depositing a dielectric material over the dummy gate structures 140 using suitable deposition processes. An anisotropic etching process is then performed on the deposited spacer material layer to expose portions of the fin structure 125 not covered by the dummy gate structures 140 (e.g., over the source/drain regions S/D of the fin structure 125). Portions of the spacer material layer directly above the dummy gate structures 140 may be completely removed by this anisotropic etching process. Portions of the spacer material layer on sidewalls of the dummy gate structures 140 may remain, forming gate sidewall spacers, which are denoted as the gate spacers 150, for the sake of simplicity.

Reference is made to FIG. 4. Exposed portions of the fin structure 125 that extend laterally beyond the gate spacers 150 (e.g., in source/drain regions S/D of the fin structure 125) are etched by using, for example, an anisotropic etching process that uses the dummy gate structures 140 and the gate spacers 150 as an etch mask, resulting in recesses R1 into the fin structure 125. After the anisotropic etching, end surfaces of the semiconductor layers 122a, 122b, 124a, 124b, 126 and respective outermost sidewalls of the gate spacers 150 are substantially coterminous, due to the anisotropic etching. In some embodiments, the anisotropic etching may be performed by a dry chemical etch with a plasma source and a reaction gas. The plasma source may be an inductively coupled plasma (ICP) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof.

Reference is made to FIGS. 5A and 5B, where FIG. 5B is a cross-sectional view taken along line II-II of FIG. 5A. The semiconductor layers 126 (see FIG. 4) are removed, resulting in openings between the topmost semiconductor layers 124a and the bottommost semiconductor layers 124b. Subsequently, middle dielectric isolators 160 are filled in the openings, respectively, such that the middle dielectric isolators 160 are between the semiconductor layers 124a and 124b. For example, a dielectric material layer is formed to fill the opening. The dielectric material layer may be a low-k dielectric material, such as SiO₂, SiN, SiC, SiON, SiCN, or SiOCN, and may be formed by a suitable deposition method, such as ALD. In some embodiments, the dielectric material layer is intrinsic or un-doped with impurities. The dielectric material layer can be formed using CVD, including LPCVD and PECVD, PVD, ALD, or other suitable processes.

After the deposition of the dielectric material layer, an anisotropic etching process may be performed to remove the dielectric material layer outside the openings, such that portions of the deposited dielectric material layer that fill the openings are left. After the etching process, the remaining portions of the deposited spacer material in the openings are denoted as the middle dielectric isolators 160, for the sake of simplicity. The middle dielectric isolator 160 serves to isolate the semiconductor layers 124a from the semiconductor layers 124b.

The semiconductor layers 122a and 122b are then laterally or horizontally recessed by using suitable etch techniques, resulting in lateral recesses each vertically between corresponding semiconductor layers 124a and 124b. These operations may be performed by using selective etching processes. In some embodiments, the selective dry etching etches SiGe at a faster etch rate than it etches Si.

Subsequently, inner dielectric spacers 165 are filled in the recesses, respectively. For example, spacer material layers are formed and then trimmed to fill the recesses. The spacer material layer may be a low-k dielectric material, such as SiO₂, SiN, SiC, SiON, SiCN, or SiOCN, and may be formed by a suitable deposition method, such as ALD. In some embodiments, the spacer material layer is intrinsic or un-doped with impurities. The spacer material layer can be formed using CVD, including LPCVD and PECVD, PVD, ALD, or other suitable processes.

Next, bottom source/drain epitaxial structures 170, top source/drain epitaxial structures 175, a contact etch stop layer (CESL) 190, and an interlayer dielectric (ILD) layer 195 are sequentially formed in the recesses R1 of the fin structure 125. In some embodiments, the semiconductor layers 124a and 124b are laterally or horizontally recessed by using suitable etch techniques, resulting in lateral recesses each vertically between corresponding inner dielectric spacers 165. Subsequently, first semiconductor materials are deposited in the recesses R1 to form the bottom source/drain epitaxial structures 170. In some embodiments, each of the bottom source/drain epitaxial structures 170 includes first epitaxial portions 172 connected to the semiconductor layers 124a and a second epitaxial portion 174 connected to the first epitaxial portions 172. The first epitaxial portions 172 and the second epitaxial portion 174 may be formed of different semiconductor materials and may be doped to different impurities. Similarly, second semiconductor materials are deposited in the recesses R1 to form the top source/drain epitaxial structures 175. In some embodiments, each of the top source/drain epitaxial structures 175 includes first epitaxial portions 176 connected to the semiconductor layers 124b and a second epitaxial portion 178 connected to the first epitaxial portions 176. The first epitaxial portions 176 and the second epitaxial portion 178 may be formed of different semiconductor materials and may be doped to different impurities.

Specifically, the bottom source/drain epitaxial structures 170 are on opposite sides and connected to the semiconductor layers 124a and spaced apart from the semiconductor layers 124b. The top source/drain epitaxial structures 175 are on opposite sides and connected to the semiconductor layers 124b and spaced apart from the semiconductor layers 124a. The bottom source/drain epitaxial structures 170 and the top source/drain epitaxial structures 175 may be formed by performing an epitaxial growth process that provides epitaxial materials in the recesses R1. In some embodiments, the lattice constants of the bottom source/drain epitaxial structures 170 are different from the lattice constant of the semiconductor layers 124a, so that the semiconductor layers 124a can be strained or stressed by the bottom source/drain epitaxial structures 170 to improve carrier mobility of the semiconductor device and enhance the device performance. Similarly, the lattice constants of the top source/drain epitaxial structures 175 are different from the lattice constant of the semiconductor layers 124b. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the semiconductor layers 124a or 124b.

In some embodiments, the bottom source/drain epitaxial structures 170 and the top source/drain epitaxial structures 175 may include Ge, Si, GaAs, AlGaAs, SiGe, GaAsP, SiP, or other suitable material. The bottom source/drain epitaxial structures 170 and the top source/drain epitaxial structures 175 may be in-situ doped during the epitaxial process by introducing doping species including: p-type dopants, such as boron or BF₂; n-type dopants, such as phosphorus or arsenic; and/or other suitable dopants including combinations thereof. If the bottom source/drain epitaxial structures 170 and/or the top source/drain epitaxial structures 175 are not in-situ doped, an implantation process (i.e., a junction implant process) is performed to dope the bottom source/drain epitaxial structures 170 and/or the top source/drain epitaxial structures 175.

In some embodiments, after the bottom source/drain epitaxial structures 170 are formed, at least one or some of the bottom source/drain epitaxial structures 170 are removed according to specific circuit designs (e.g., SRAM layout designs). For example, a mask is formed over the dummy gate structures 140 and some of the bottom source/drain epitaxial structures 170. The mask exposes at least one of the bottom source/drain epitaxial structures 170. Subsequently, an etching process is performed to remove the bottom source/drain epitaxial structure 170 exposed by the mask. In some embodiments, some of the first epitaxial portions 172 remain on the sidewalls of the semiconductor layers 124a after the etching process. After the etching process, the mask is removed.

The CESL 190 is then formed on the substrate 110 and covers the bottom source/drain epitaxial structures 170 and the top source/drain epitaxial structures 175. In some examples, the CESL 190 includes a silicon nitride layer, silicon oxide layer, a silicon oxynitride layer, and/or other suitable materials. The CESL 190 may be formed by plasma-enhanced chemical vapor deposition (PECVD) process and/or other suitable deposition or oxidation processes.

The ILD layer 195 is formed over the CESL 190. In some embodiments, the ILD layer 195 includes materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL 190. The ILD layer 195 may be deposited by a PECVD process or other suitable deposition technique.

In some examples, after depositing the ILD layer 195, a planarization process may be performed to remove excessive materials of the ILD layer 195. For example, a planarization process includes a chemical mechanical planarization (CMP) process which removes portions of the ILD layer 195 and the CESL 190 overlying the dummy gate structures 140 and planarizes a top surface of the semiconductor device 100a. In some embodiments, the CMP process also removes hard masks 146 (as shown in FIG. 4) and exposes the dummy gate electrode layers 144.

Reference is made to FIGS. 6A and 6B, where FIG. 6B is a cross-sectional view taken along line III-III of FIG. 6A. Thereafter, the dummy gate structures 140 (as shown in FIG. 5A) are removed first, and then the semiconductor layers (i.e., sacrificial layers) 122a and 122b (as shown in FIG. 5A) are removed. In some embodiments, the dummy gate structures 140 are removed by using a selective etching process (e.g., selective dry etching, selective wet etching, or combinations thereof) that etches the materials in dummy gate structures 140 at a faster etch rate than it etches other materials (e.g., the gate spacers 150, and/or the ILD layer 195), thus resulting in gate trenches GT1 between corresponding gate spacers 150, with the semiconductor layers 122a and 122b exposed in the gate trenches GT1. Subsequently, the semiconductor layers 122a and 122b in the gate trenches GT1 are removed by using another selective etching process that etches the semiconductor layers 122a and 122b at a faster etch rate than it etches the semiconductor layers 124a and 124b, thus forming openings O1 between neighboring semiconductor layers (i.e., channel layers) 124a and 124b. In this way, the semiconductor layers 124a (124b) become nanosheets suspended over the substrate 110 and between the bottom source/drain epitaxial structures 170 (the top source/drain epitaxial structures 175). This operation is also called a channel release process. In some embodiments, the semiconductor layers 124a and 124b can be interchangeably referred to as nanostructures, nanowires, nanoslabs and nanorings, depending on their geometry. For example, in some other embodiments the semiconductor layers 124a and 124b may be trimmed to have a substantial rounded shape (i.e., cylindrical) due to the selective etching process for completely removing the semiconductor layers 122a and 122b. In that case, the resultant semiconductor layers 124a and 124b can be called nanowires.

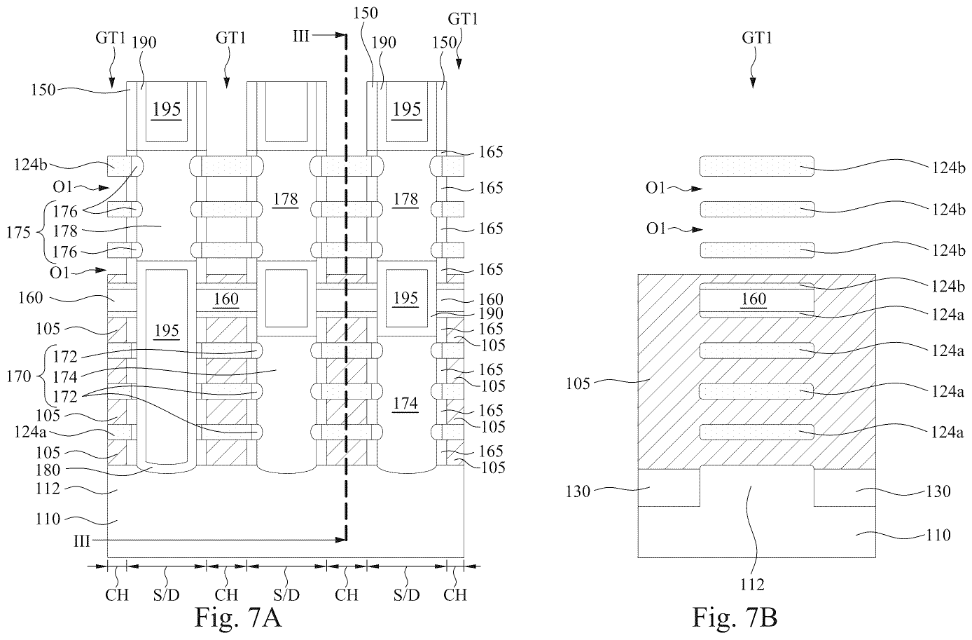

Reference is made to FIGS. 7A and 7B, where FIG. 7B is a cross-sectional view taken along line III-III of FIG. 7A. Protection materials 105 are formed in the gate trenches GT1. In greater detail, the protection materials 105 may be formed by, for example, depositing dielectric materials filling the gate trenches GT1. The dielectric materials are then etched back to expose the gate spacers 150 and the semiconductor layers 124b. After the etching back process, the dielectric materials still cover the semiconductor layers 124a, and the remaining portions of the deposited dielectric materials in the gate trenches GT1 are denoted as the protection materials 105. In some embodiments, after the etching back process, the protection materials 105 still cover the bottommost semiconductor layers 124b and the middle dielectric isolators 160. In some embodiments, the protection materials 105 may be made of SiOC, SiOₓ, the like, or other suitable material.

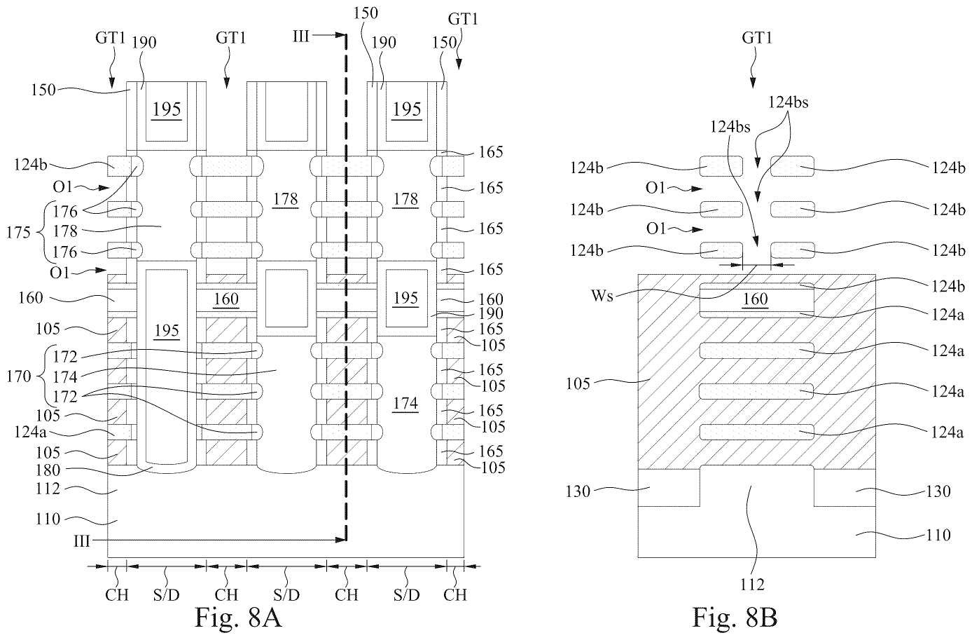

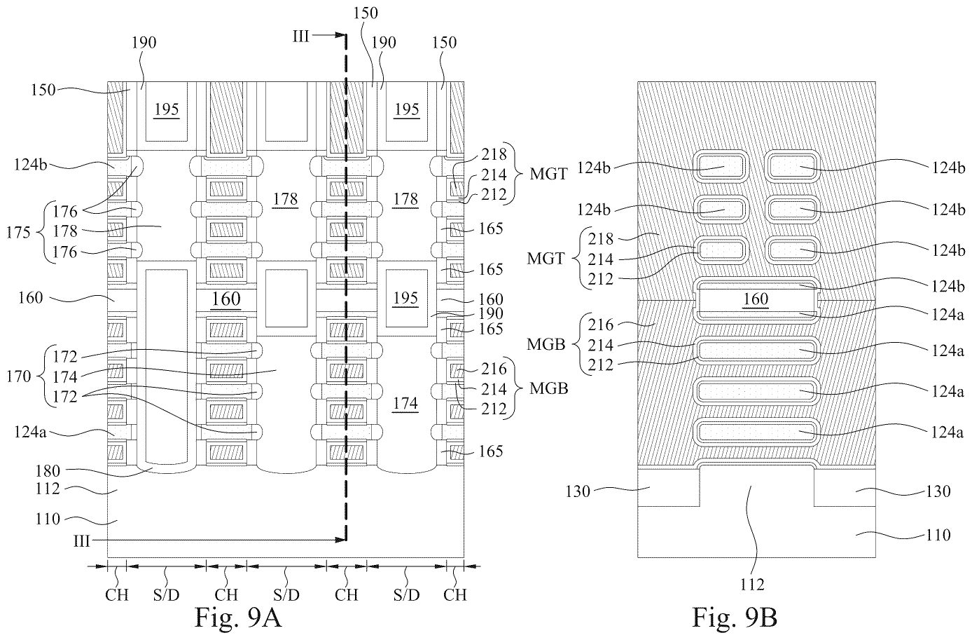

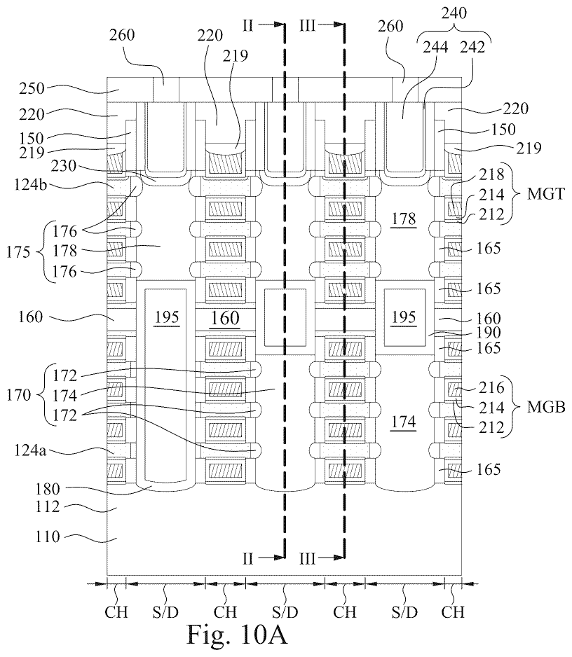

Reference is made to FIGS. 8A and 8B, where FIG. 8B is a cross-sectional view taken along line III-III of FIG. 8A. An etching process is performed to the semiconductor layers 124b. Specifically, an etching mask is formed over the structure of FIGS. 7A and 7B, and the etching mask is patterned to expose center portions of the semiconductor layers 124b. The center portions of the semiconductor layers 124b are then removed, such that each of the semiconductor layers 124b are patterned to be two portions as shown in FIG. 8B, and slits 124bs are formed in the semiconductor layers 124b. In some embodiments, the slit 124bs has a width Ws in a range of about 4 nm to about 6 nm. If the width Ws is less than about 4 nm, the following formed work function metal layer 218 (see FIG. 9B) may not be formed in the slits 124bs; if the width Ws is greater than about 6 nm, contact areas between the following formed top gate structure MGT (see FIG. 9B) and the semiconductor layers 124b may be small.

In some embodiments, the semiconductor layers 124b are patterned by using an anisotropic etching process by using, for example, HF and Cl₂ as etching gases. The anisotropic etching process is performed with a first etching rate in a vertical direction higher than a second etching rate in a horizontal direction. In some embodiments, a time duration of the etching process is in a range of about 40 seconds to about 50 seconds. If the time duration is longer than about 50 seconds, the second etching rate in the horizontal direction of the etching process may be raised; if the time duration is less than about 40 seconds, the etching gas may not reach to the bottommost semiconductor layer 124b.

Reference is made to FIGS. 9A and 9B, where FIG. 9B is a cross-sectional view taken along line III-III of FIG. 9A. After the etching process as shown in FIGS. 8A and 8B, the etching mask is removed, and then the protection materials 105 (see FIGS. 8A and 8B) are also removed to expose the semiconductor layers 124a. Thereafter, bottom (metal) gate structures MGB and top (metal) gate structures MGT are formed in the gate trenches GT1 and the openings O1. Further, portions of the top gate structure MGT are in the slits 124bs (see FIG. 8B) of the semiconductor layers 124b.

Specifically, interfacial layers 212 are formed around the semiconductor layers 124a and 124b. In some embodiments, the interfacial layer 212 may include a dielectric material such as silicon oxide (SiO₂), HfSiO, or silicon oxynitride (SiON). The interfacial layers 212 may be formed by chemical oxidation, thermal oxidation, atomic layer deposition (ALD), chemical vapor deposition (CVD), and/or other suitable method. In some embodiments, when the interfacial layers 212 are formed by oxidation, the interfacial layers 212 are grown on the surfaces of semiconductor materials, such as the semiconductor layers 124a and 124b.

Thereafter, high-k gate dielectric layers 214 are formed to cover the interfacial layers 212. High-k gate dielectrics include dielectric materials having a high dielectric constant, for example, greater than that of thermal silicon oxide (˜3.9). The high-k gate dielectric layer 214 of the gate dielectric layer may include hafnium oxide (HfO₂). Alternatively, the high-k gate dielectric layer 214 may include other high-k dielectrics, such as hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof. The high-k gate dielectric layers 214 may be formed by atomic layer deposition (ALD), chemical vapor deposition (CVD), and/or other suitable method.

Next, a work function metal layer 216 is deposited in the gate trenches and fills the gate trenches. The work function metal layer 216 may include work function metals to provide a suitable work function for bottom (metal) gate structures MGB. For a p-type FET, the work function metal layer 216 may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. The work function metal layer 216 may be formed by atomic layer deposition (ALD), chemical vapor deposition (CVD), and/or other suitable method. Subsequently, one or more CMP processes are performed to remove excessive gate materials.

After the formation of the work function metal layer 216, the work function metal layer 216 is etched back by using an etching process, and the top portions of the high-k gate dielectric layers 214 are exposed. Subsequently, another work function metal layer 218 is deposited in the gate trenches and over the work function metal layer 216 and fills the gate trenches GT1. Portions of the work function metal layer 218 are in the slits 124bs (see FIG. 8B). For an n-type FET, the work function metal layer 218 may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials.

Therefore, the interfacial layers 212, the high-k gate dielectric layers 214, and the work function metal layer 216 form the bottom (metal) gate structures MGB, and the interfacial layers 212, the high-k gate dielectric layers 214, and the work function metal layer 218 form the top (metal) gate structures MGT over the bottom gate structures MGB.

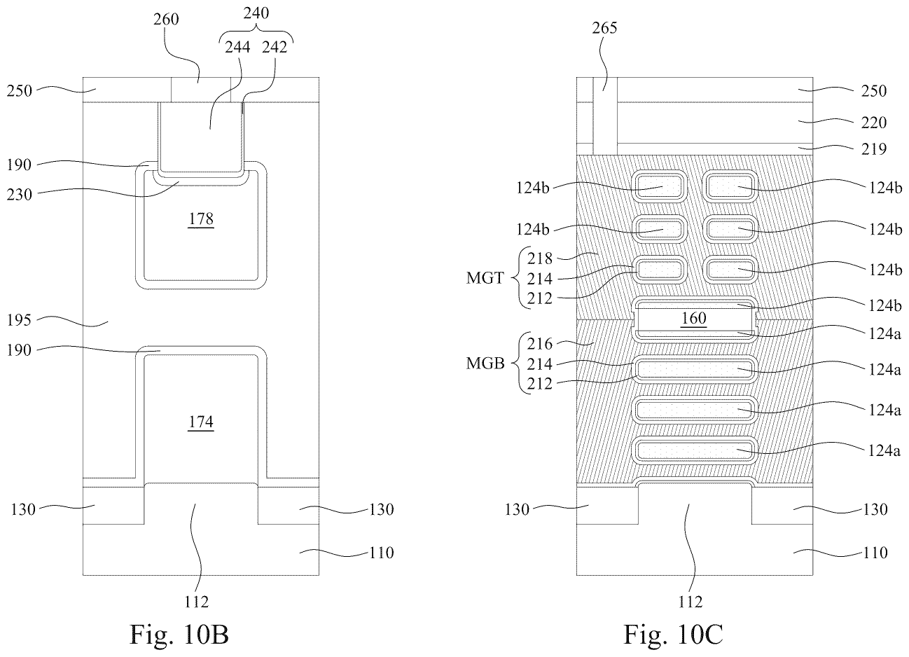

Reference is made to FIGS. 10A-10C, where FIG. 10B is a cross-sectional view taken along line II-II of FIG. 10A, and FIG. 10C is a cross-sectional view taken along line III-III of FIG. 10A. An etching back process is performed to etch back the top gate structures MGT and the gate spacers 150, resulting in recesses over the etched-back top gate structures MGT and the etched-back gate spacers 150. In some embodiments, because the materials of the top gate structures MGT have a different etch selectivity than the gate spacers 150, a first selective etching process may be initially performed to etch back the top gate structures MGT to lower the top gate structures MGT. Then, a second selective etching process is performed to lower the gate spacers 150. As a result, the top surfaces of the top gate structures MGT may be at a different level than the top surfaces of the gate spacers 150. For example, in the depicted embodiment as illustrated in FIG. 10A, the top gate structures MGT has top surfaces lower than the top surfaces of the gate spacers 150. However, in some other embodiments, the top surfaces of the top gate structures MGT may be level with or higher than the top surfaces of the gate spacers 150.

Subsequently, metal caps 219 are formed respectively atop the top gate structures MGT by suitable process, such as CVD or ALD. In some embodiments, the metal caps 219 are formed on the top gate structures MGT using a bottom-up approach. For example, the metal caps 219 are selectively grown on the metal surface, such as the work function metal layer 216, and thus the sidewalls of the gate spacers 150 are substantially free from the growth of the metal caps 219. The metal caps 219 may be, by way of example and not limitation, substantially fluorine-free tungsten (FFW) films having an amount of fluorine contaminants less than 5 atomic percent and an amount of chlorine contaminants greater than 3 atomic percent. The FFW films or the FFW-including films may be formed by ALD or CVD using one or more non-fluorine based tungsten precursors such as, but not limited to, tungsten pentachloride (WCl₅), tungsten hexachloride (WCl₆). In some embodiments, portions of the metal caps 219 may overflow over the high-k gate dielectric layers 214, such that the metal caps 219 may also cover the exposed surface of the high-k gate dielectric layers 214. In some embodiments, the formation of the metal caps 219 is omitted.

Next, a dielectric cap layer is deposited over the substrate 110 until the recesses are overfilled. The dielectric cap layer includes SiN, SiC, SiCN, SiON, SiCON, combinations thereof or the like, and is formed by a suitable deposition technique such as CVD, plasma-enhanced CVD (PECVD), ALD, remote plasma ALD (RPALD), plasma-enhanced ALD (PEALD), combinations thereof or the like. A CMP process is then performed to remove the cap layer outside the recesses, leaving portions of the dielectric cap layer in the recesses to serve as dielectric caps 220. In some embodiments, the formation of the dielectric caps 220 is omitted.

Subsequently, openings are formed in the ILD layer 195. The opening exposes the top source/drain epitaxial structures 175. Front-side metal alloy layers 230 are then respectively formed above the top source/drain epitaxial structures 175. The front-side metal alloy layers 230, which may be silicide layers, are respectively formed over the exposed top source/drain epitaxial structures 175 by a self-aligned silicide (salicide) process. The silicide process converts the surface portions of the top source/drain epitaxial structures 175 into the silicide contacts. Silicide processing involves deposition of a metal that undergoes a silicidation reaction with silicon (Si). In order to form silicide contacts on the top source/drain epitaxial structures 175, a metal material is blanket deposited on the top source/drain epitaxial structures 175. After heating the wafer to a temperature at which the metal reacts with the silicon of the top source/drain epitaxial structures 175 to form the front-side metal alloy layers 230, unreacted metal is removed. The silicide layers remain over the top source/drain epitaxial structures 175, while unreacted metal is removed from other areas. The silicide layer may include a material selected from titanium silicide, cobalt silicide, nickel silicide, platinum silicide, nickel platinum silicide, erbium silicide, palladium silicide, combinations thereof, or other suitable materials. In some embodiments, the front-side metal alloy layer 230 may include germanium.

Front-side source/drain contacts 240 are then respectively formed in the openings and on the front-side metal alloy layers 230. In some embodiments, barrier layers 242 are formed on the front-side metal alloy layers 230 and in the openings. The barrier layers 242 can improve the adhesion between the CESL layer 190 and a material formed thereon (such as the filling materials 244). The barrier layers 242 may include metal nitride materials. For example, the barrier layers 242 include Ti, TiN, or combinations thereof. In some embodiments, the barrier layers 242 include a single layer or multiple layers. For a multiple-layer configuration, the layers include different compositions of metal nitride from each other. For example, the barrier layer 242 has a first metal nitride layer including Ti and a second metal nitride layer including TiN.

Filling materials 244 are formed in the openings and over the barrier layers 242. The filling materials 244 are electrically connected to the top source/drain epitaxial structures 175. In some embodiments, metal materials can be filled in the openings, and excessive portions of the metal materials and the barrier layer are removed by performing a CMP process to form the filling materials 244 and the barrier layer 242. The filling materials 244 can be made of tungsten, aluminum, copper, or other suitable materials. The filling materials 244 and the barrier layers 242 are referred to as the front-side source/drain contacts 240.

An ILD layer 250 is then formed over the substrate 110. In some embodiments, the ILD layer 250 includes materials similar to or the same as the ILD layer 195. The ILD layer 250 may be deposited by a PECVD process or other suitable deposition technique. A plurality of holes are then formed in the ILD layer 250 (and the dielectric caps 220) by using at least one etching process.

Source/drain vias 260 and at least one gate via 265 are then formed to fill the holes. The source/drain vias 260 and the gate via 265 are formed using, by way of example and not limitation, depositing one or more metal materials overfilling the holes, followed by a CMP process to remove excessive metal material(s) outside the holes. As a result of the CMP process, the source/drain vias 260 and the gate via 265 have top surfaces substantially coplanar with the ILD layer 250. The source/drain vias 260 and the gate via 265 may include metal materials such as copper, aluminum, tungsten, combinations thereof, or the like, and may be formed using PVD, CVD, ALD, or the like. In some embodiments, the source/drain vias 260 and the gate via 265 may further include one or more barrier/adhesion layers (not shown) to protect the ILD layer 250 from metal diffusion (e.g., copper diffusion). The one or more barrier/adhesion layers may include titanium, titanium nitride, tantalum, tantalum nitride, or the like, and may be formed using PVD, CVD, ALD, or the like.

Reference is made to FIGS. 11A-11C, where FIG. 11B is a cross-sectional view taken along line II-II of FIG. 11A, and FIG. 11C is a cross-sectional view taken along line III-III of FIG. 11A. The structure illustrated in FIGS. 10A-10C is “flipped” upside down, and the substrate 110 (see FIGS. 10A-10C) is thinned to expose the isolation structures 130 and the base portion 112 (see FIGS. 10A-10C). In some embodiments, the substrate 110 is thinned down from the backside thereof until the isolation structures 130 are exposed.

The base portion 112 of the substrate 110 are then patterned to form openings extending through the base portion 112 by using one or more etching process(es). After the one or more etching process(es), the openings expose portions of the bottom source/drain epitaxial structures 170.

Backside metal alloy layers 270 are then formed in the openings and cover the bottom source/drain epitaxial structures 170. Materials, configurations, dimensions, processes and/or operations regarding the backside metal alloy layers 270 are similar to or the same as the front-side metal alloy layers 230 described in FIGS. 10A-10C.

Backside source/drain contacts 280 are then respectively formed in the openings and on the backside metal alloy layers 270. In some embodiments, barrier layers 282 are formed on the backside metal alloy layers 270 and in the openings. Materials, configurations, dimensions, processes and/or operations regarding the barrier layers 282 are similar to or the same as the barrier layers 242 described in FIGS. 10A-10C. Filling materials 284 are then formed in the openings and over the barrier layers 282. Materials, configurations, dimensions, processes and/or operations regarding the filling materials 284 are similar to or the same as the filling materials 244 described in FIGS. 10A-10C. The filling materials 284 and the barrier layers 282 are referred to as the backside source/drain contacts 280.

The base portion 112 and the isolation structures 130 are then removed by using a selective etching process that etches the base portion 112 (e.g., Si) and the isolation structures 130 (e.g., dielectric materials) at a faster etch rate that it etches the backside source/drain contacts 280 (e.g., metal). A backside etch stop layer 290 is conformally formed to cover the backside of the bottom gate structures MGB and the bottom source/drain epitaxial structures 170. Materials, configurations, dimensions, processes and/or operations regarding the backside etch stop layer 290 are similar to or the same as the CESL 190 of FIG. 5A. A backside ILD layer 295 is then formed on the backside etch stop layer 290 and surrounds the backside source/drain contacts 280. Materials, configurations, dimensions, processes and/or operations regarding the backside ILD layer 295 are similar to or the same as the ILD layer 195 of FIG. 5A.

As such, the semiconductor device 100a is formed. As shown in FIGS. 11A-11C, the semiconductor device 100a includes a bottom (nanostructure) transistor BT and top (nanostructure) transistors TT1 and TT2. The top transistor TT1 and the bottom transistor BT form a CFET. The top transistor TT1 is directly over the bottom transistor BT, and the top transistor TT2 is over the bottom transistor BT and shares a top source/drain epitaxial structure 175 with the top transistor TT1.

In some embodiments, the semiconductor device 100a is a static random access memory (SRAM) device. SRAM is a type of volatile semiconductor memory that uses bistable latching circuitry to store each bit. Each bit in an SRAM is stored on four transistors (PU1, PU2, PD1, and PD2) that form two cross-coupled inverters. This memory cell has two stable states which are used to denote 0 and 1. Two additional access transistors (PG1 and PG2) are electrically connected to the two cross-coupled inventers and serve to control the access to a storage cell during read and write operations. In some embodiments, the bottom transistor BT is a pull-up transistor (PU1 or PU2), the top transistor TT1 is a pull-down transistor (PD1 or PD2), and the top transistor TT2 is a pass gate transistor (PG1 or PG2). Therefore, two sets of the structure shown in FIG. 11A may form a 6T SRAM device.

The bottom transistor BT includes the channel structures (or channel layers) 124a, the bottom source/drain epitaxial structures 170 on opposite sides of the channel structures 124a and connected to the channel structures 124a, and the bottom gate structure MGB wrapping around the channel structures 124a. Each of the top transistors TT1 and TT2 includes the channel structures 124b, the top source/drain epitaxial structures 175 on opposite sides of the channel structures 124b and connected to the channel structures 124b, and the top gate structure MGT wrapping around the channel structures 124b. The bottom transistor BT is a P-type transistor, and the top transistors TT1 and TT2 are N-type transistors, or vice versa.

As shown in FIG. 11C, the channel structures 124a are arranged in a stacking direction (Z-axis in this case). On the other hand, the channel structures 124b are arranged both in the stacking direction and a second direction (Y-axis in this case) substantially perpendicular to a first direction where the channel structures 124a and 124b extending (X-axis in this case). In the embodiments shown in FIG. 11C, the channel structures 124b are arranged as a 2 by 3 matrix. In some other embodiment, however, the channel structures 124b can be arranged as an n by m matrix, where n and m are integers and n is greater than 1. Therefore, a contact area (and thus the channel effective width) between the top gate structure MGT and the channel structures 124b is greater than a contact area (and thus the channel effective width) between the bottom gate structure MGB and the channel structures 124a. Such configuration improves the device performance and is less current crowding.

Specifically, take an SRAM device as an example, the increasing of the channel effective width in the top transistors TT1 and TT2 improves the SRAM operation speed boost by more than about 10%. Further, the increasing of the channel effective width also increases the saturated current (Idsat) of the transistors TT1 and TT2 (i.e., the transistors PD and PG in this case), and the SRAM cell Vccmin is also improved by more than about 20%. Therefore, the read/write margin of the SRAM device is also improved. The matrix arrangement of the channel structures 124b also improves the current crowding issue of the semiconductor device 100a.

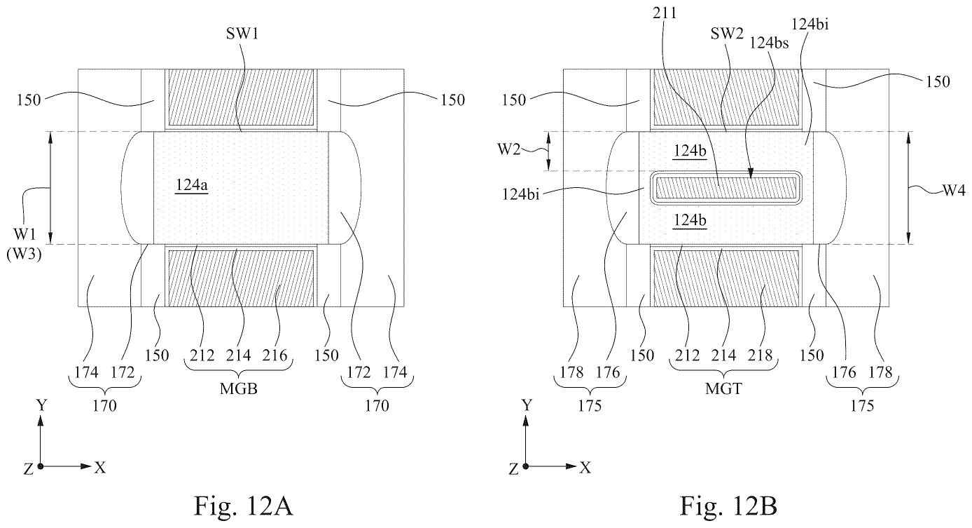

FIG. 12A is a cross-sectional view taken along line A-A in FIG. 11C, and FIG. 12B is a cross-sectional view taken along line B-B in FIG. 11C. In FIG. 12A, the channel structures 124b are at the same level are arranged in the Y direction. Portions of the channel structure (i.e., the channel layers) 124b are wrapped by the top gate structure MGT, and interconnect semiconductor portions 124bi of the channel structure 124b are on opposite sides of the channel structures 124b and in contact with the top source/drain epitaxial structures 175. That is, the interconnect semiconductor portions 124bi are directly between the channel structures 124b and the top source/drain epitaxial structures 175. The interconnect semiconductor portions 124bi and the channel structures 124b forms a closed loop in a top view as shown in FIG. 12B. Stated another way, the channel structure 124b has a slit 124bs therein, and a portion 211 of the top gate structure MGT is in the slit 124bs and directly between the channel structures 124b.

A minimum width W1 of the channel structure 124a is greater than a width W2 of the channel structure 124b. However, a width W3 of the channel structure 124a is substantially equal to a width W4 of the interconnect semiconductor portions 124bi. As shown in FIGS. 11C, 12A, and 12B, an outer sidewall SW1 of the channel structure 124a is substantially aligned with an outer sidewall SW2 of the channel structure 124b. Further, as shown in FIGS. 11A and 11B, a (maximum) width W5 of (the second epitaxial portions 174 of) the bottom source/drain epitaxial structure 170 is substantially equal to a (maximum) width W6 of (the second epitaxial portions 178 of) the top source/drain epitaxial structure 175.

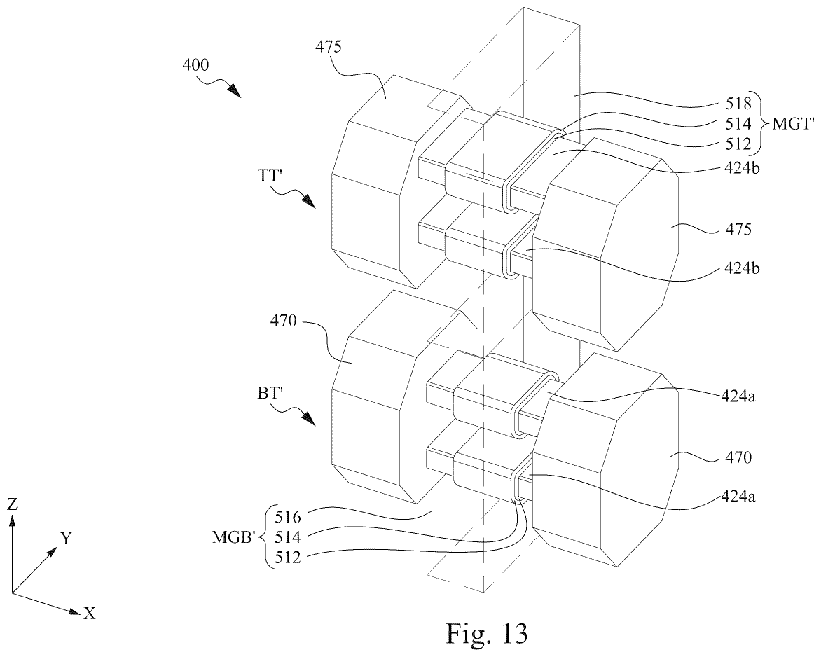

FIG. 13 is a perspective view of an integrated circuit structure (or a semiconductor device) 400 in accordance with some embodiments of the present disclosure. In the present disclosure, a semiconductor device 400 is provided, and its manufacturing method will be disclosed in the following discussion. In addition to the semiconductor device 400, FIG. 13 depicts X-axis, Y-axis, and Z-axis directions. In the semiconductor device 400, a top transistor TT′ is disposed vertically above a bottom transistor BT′. In some embodiments, the bottom transistor BT′ and the top transistor TT′ each may be a field effect transistor (FET) and may both include gate-all-around (GAA) configuration, and thus the bottom transistor BT′ and the top transistor TT′ can also be referred to as GAA FETs. The bottom transistor BT′ includes channel structures 424a vertically stacked one above another, a bottom gate structure MGB′ wrapping around each of the channel structures 424a, and bottom source/drain epitaxial structures 470 on opposite ends of each of the channel structures 424a. Similarly, the top transistor TT′ includes channel structures 424b vertically stacked one above another, a top gate structure MGT′ wrapping around each of the channel structures 424b, and top source/drain epitaxial structures 475 on opposite ends of each of the channel structures 424b. Further, each of the channel structures 424b has a width (in the Y-axis and along an extending direction of the bottom gate structures MGB′ and the top gate structures MGT′) greater than a width of the channel structures 424a.

The bottom gate structure MGB′ may include interfacial layers 512, high-k gate dielectric layers 514, and a work function metal layer 516. Similarly, the top gate structure MGT′ may include the interfacial layers 512, the high-k gate dielectric layers 514, and a work function metal layer 518. In some embodiments, the bottom transistor BT′ has a first conductivity type (e.g., p-type) and the top transistor TT′ has a second conductivity type (e.g., n-type) different from the first conductivity type. In some embodiments, the bottom transistor BT′ can be referred to as a P-FET, and the top transistor TT can be referred to as an N-FET.

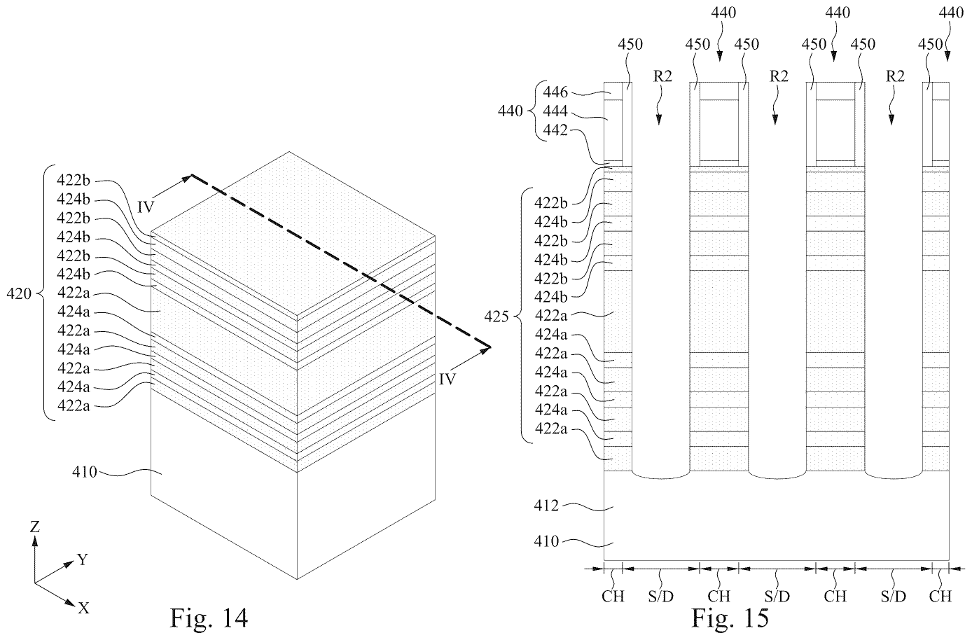

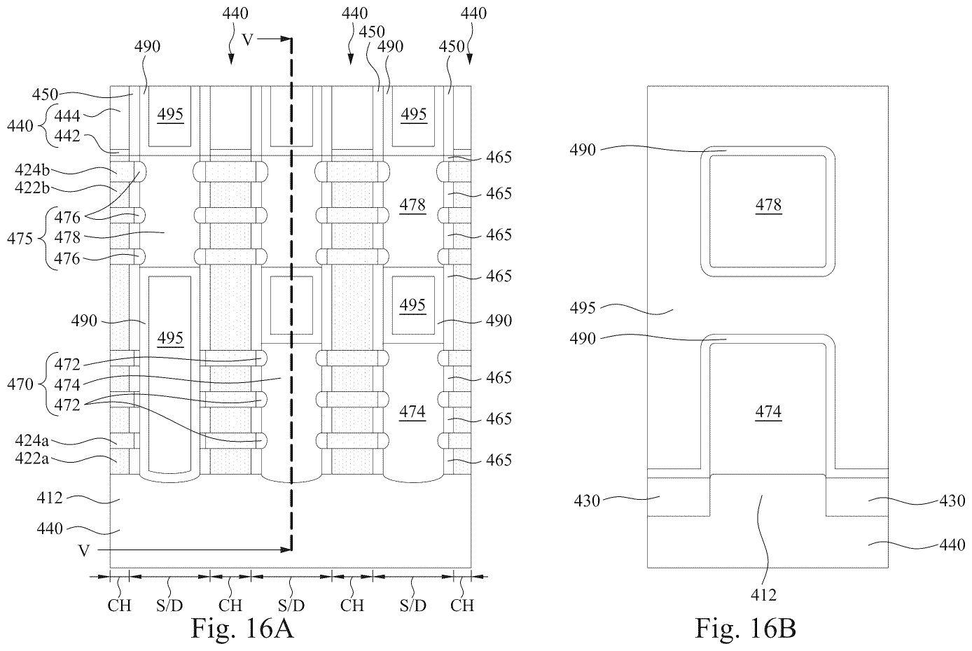

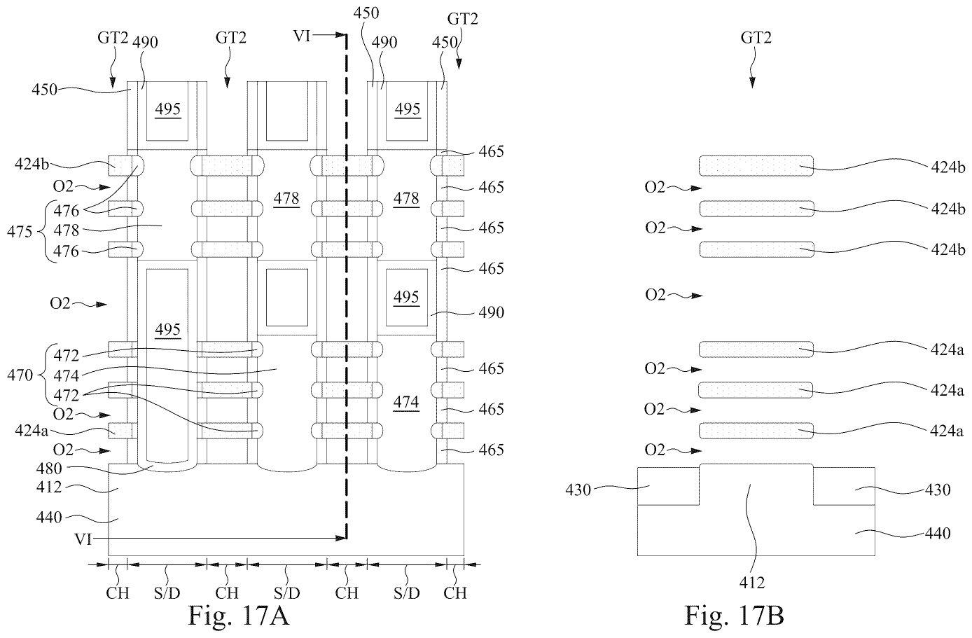

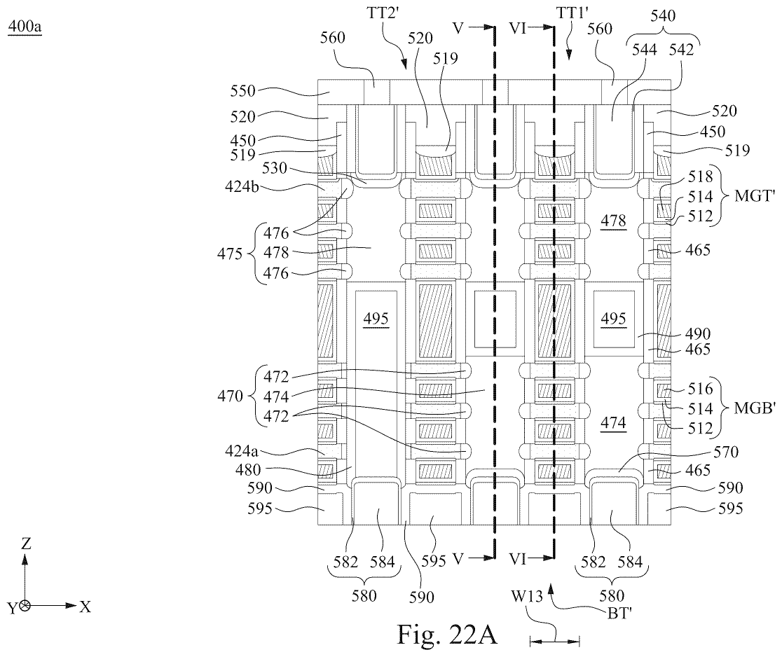

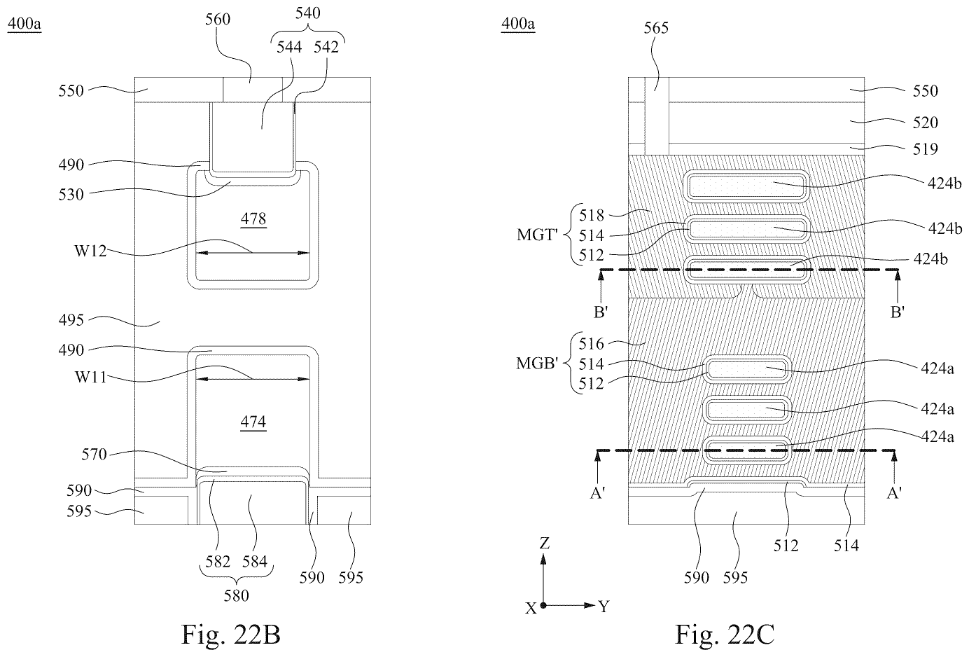

FIGS. 14-22C illustrate perspective views and cross-sectional views of intermediate stages in the formation of an integrated circuit structure (or a semiconductor device) 400a in accordance with some embodiments of the present disclosure. In some embodiments, the semiconductor device 400a in FIGS. 22A-22C is a complementary FET (CFET) device. In addition to the semiconductor device 400a, FIGS. 14, 22A, and 22C depicts X-axis, Y-axis, and Z-axis directions. FIGS. 15, 16A, 17A, 18A, 19A, 20A, 21A, and 22A are cross-sectional views of some embodiments of the semiconductor device 400a at intermediate stages along a first cut (e.g., cut IV-IV in FIG. 14). FIGS. 16B, 21B, and 22B are cross-sectional views of some embodiments of the semiconductor device 400a at intermediate stages along a second cut (e.g., cut V-V in FIGS. 16A, 21A, and 22A). FIGS. 17B, 18B, 19B, 20B, 21C, and 22C are cross-sectional views of some embodiments of the semiconductor device 400a at intermediate stages along a third cut (e.g., cut VI-VI in FIGS. 17A, 18A, 19A, 20A, 21A, and 22A). The formed devices include a p-type transistor (such as p-type GAA FET) and an n-type transistor (such as an n-type GAA FET) in accordance with some exemplary embodiments. Throughout the various views and illustrative embodiments, like reference numbers are used to designate like elements. It is understood that additional operations can be provided before, during, and after the processes shown by FIGS. 14-22C, and some of the operations described below can be replaced or eliminated, for additional embodiments of the method. The order of the operations/processes may be interchangeable.

Referring to FIG. 14, a semiconductor stack 420 is formed over a substrate 410. Materials, configurations, dimensions, processes and/or operations regarding the substrate 410 are similar to or the same as the substrate 110 of FIG. 2. The semiconductor stack 420 includes semiconductor layers 422a and 422b interposed by semiconductor layers 424a and 424b arranged in a stacking direction (Z-axis in this case). Materials, configurations, dimensions, processes and/or operations regarding the semiconductor layers 422a and 422b are similar to or the same as the semiconductor layers 122a and 122b of FIG. 2, and materials, configurations, dimensions, processes and/or operations regarding the semiconductor layers 424a and 424b are similar to or the same as the semiconductor layers 124a and 124b of FIG. 2.

Reference is made to FIG. 15, where FIG. 15 is a cross-sectional view taken along line IV-IV of FIG. 14 in the following process stage of forming the semiconductor device 400a according to some embodiments. The structure of FIG. 14 undergoes the processes similar to the processes shown in FIGS. 3A-4. Specifically, at least one fin structure 425 extending from the substrate 110 are formed over the base portion 412 formed from the substrate 410. Next, isolation structures 430 (see FIG. 16B) are formed to surround the fin structure 425. Materials, configurations, dimensions, processes and/or operations regarding the isolation structures 430 are similar to or the same as the isolation structures 130 of FIGS. 3A and 3B.

At least one dummy gate structure 440 is formed over the substrate 410 and across the fin structure 425. The portions of the fin structure 425 underlying the dummy gate structures 440 may be referred to as the channel regions CH. The dummy gate structures 440 may also define source/drain regions S/D of the fin structure 425, for example, the regions of the fin structure 425 adjacent and on opposite sides of the channel regions CH. The dummy gate structures 440 each includes a dummy gate dielectric layer 442, a dummy gate electrode layer 444 and a hard mask 446. Materials, configurations, dimensions, processes and/or operations regarding the dummy gate structures 440 are similar to or the same as the dummy gate structures 140 of FIGS. 3A and 3B.

After the formation of the dummy gate structures 440 is completed, gate spacers 450 are formed on opposite sidewalls of the dummy gate structures 440. Materials, configurations, dimensions, processes and/or operations regarding the gate spacers 450 are similar to or the same as the gate spacers 150 of FIGS. 3A and 3B.

Exposed portions of the fin structure 425 that extend laterally beyond the gate spacers 450 (e.g., in source/drain regions S/D of the fin structure 425) are etched by using, for example, an anisotropic etching process that uses the dummy gate structures 440 and the gate spacers 450 as an etch mask, resulting in recesses R2 into the fin structure 425.

Reference is made to FIGS. 16A and 16B, where FIG. 16B is a cross-sectional view taken along line V-V of FIG. 16A. The structure of FIG. 15 undergoes the processes similar to the processes shown in FIGS. 5A-5B. Specifically, the semiconductor layers 422a and 422b are laterally or horizontally recessed by using suitable etch techniques, resulting in lateral recesses each vertically between corresponding semiconductor layers 424a and 424b. Subsequently, inner dielectric spacers 465 are filled in the recesses, respectively. Materials, configurations, dimensions, processes and/or operations regarding the inner dielectric spacers 465 are similar to or the same as the inner dielectric spacers 165 of FIG. 5A.

Next, bottom source/drain epitaxial structures 470, top source/drain epitaxial structures 475, a CESL 490, and an ILD layer 495 are sequentially formed in the recesses R2 of the fin structure 425. The bottom source/drain epitaxial structures 470 may include first epitaxial portions 472 and second epitaxial portions 474, and/or the top source/drain epitaxial structures 475 may include first epitaxial portions 476 and second epitaxial portions 478. In some embodiments, after the bottom source/drain epitaxial structures 470 are formed, at least one or some of the bottom source/drain epitaxial structures 470 are removed according to specific circuit designs (e.g., SRAM layout designs).

Materials, configurations, dimensions, processes and/or operations regarding the bottom source/drain epitaxial structures 470 are similar to or the same as the bottom source/drain epitaxial structures 170 of FIG. 5A. Materials, configurations, dimensions, processes and/or operations regarding the top source/drain epitaxial structures 475 are similar to or the same as the top source/drain epitaxial structures 175 of FIG. 5A. Materials, configurations, dimensions, processes and/or operations regarding the CESL 490 are similar to or the same as the CESL 190 of FIG. 5A. Materials, configurations, dimensions, processes and/or operations regarding the ILD layer 495 are similar to or the same as the ILD layer 195 of FIG. 5A.

Reference is made to FIGS. 17A and 17B, where FIG. 17B is a cross-sectional view taken along line VI-VI of FIG. 17A. Thereafter, the dummy gate structures 440 (as shown in FIG. 16A) are removed first, and then the semiconductor layers (i.e., sacrificial layers) 422a and 422b (as shown in FIG. 16A) are removed, thus resulting in gate trenches GT2 between corresponding gate spacers 450 and openings O2 between neighboring semiconductor layers (i.e., channel layers) 424a and 424b.

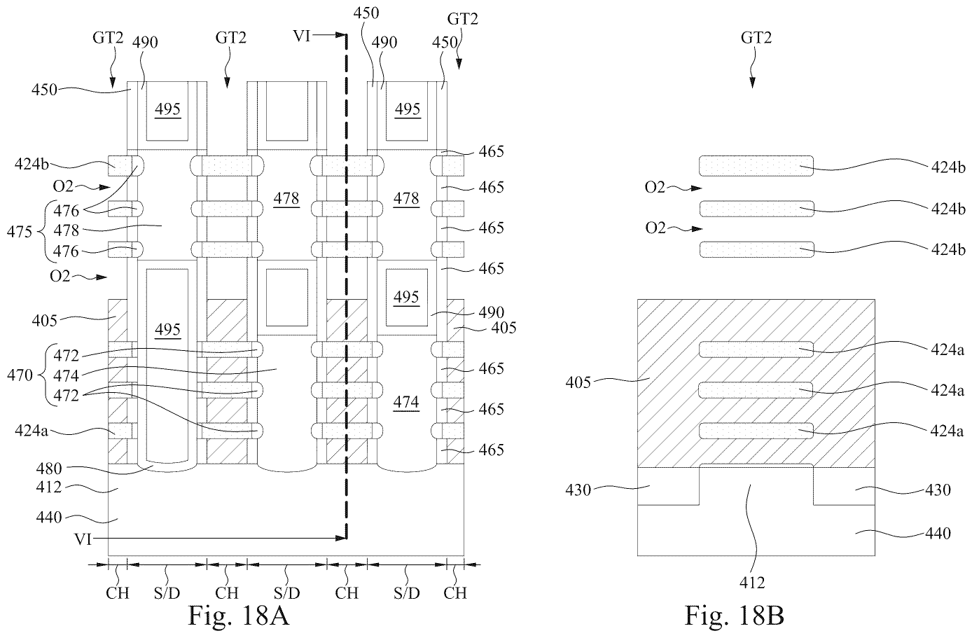

Reference is made to FIGS. 18A and 18B, where FIG. 18B is a cross-sectional view taken along line VI-VI of FIG. 18A. Protection materials 405 are formed in the gate trenches GT2. Materials, configurations, dimensions, processes and/or operations regarding the protection materials 405 are similar to or the same as the protection materials 105 of FIGS. 7A and 7B.

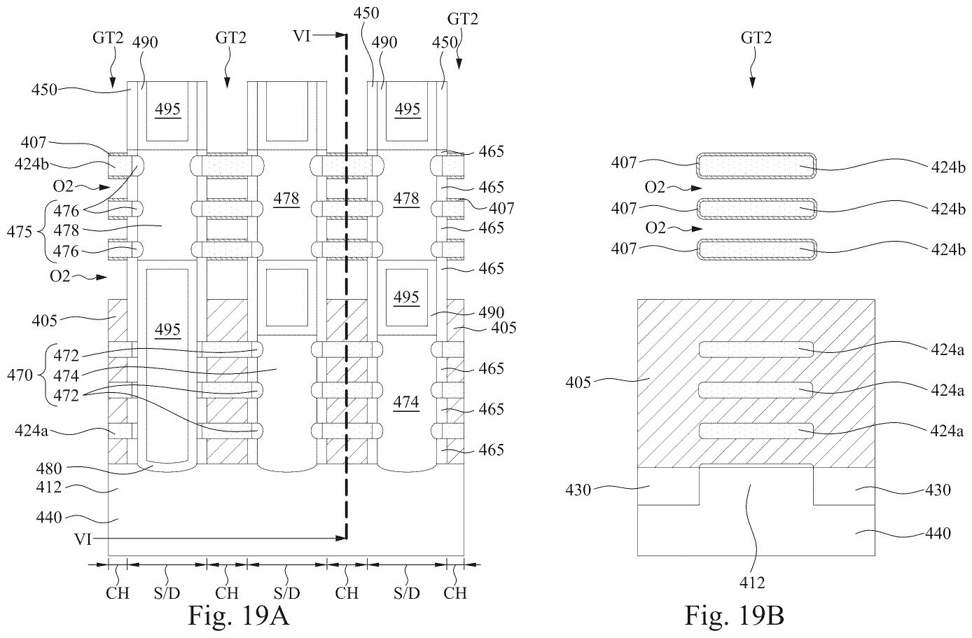

Reference is made to FIGS. 19A and 19B, where FIG. 19B is a cross-sectional view taken along line VI-VI of FIG. 19A. Dielectric layers 407 are formed to surround the semiconductor layers 424b. In some embodiments, a selective deposition process is performed to form the dielectric layers 407. In greater detail, since the semiconductor layers 424b (e.g., semiconductive materials) has a material different from the protection materials 405, the inner dielectric spacers 465, the gate spacers 450, the CESL 490, and the ILD layer 495 (e.g., dielectric materials), the selective deposition process deposits the dielectric layers 407 on the semiconductor layers 424b at a rate much faster than it deposits the dielectric layers 407 on the dielectric materials. As such, the dielectric layers 407 are formed on the surfaces of the semiconductor layers 424b. In some embodiments, the dielectric layers 407 have a material different from a material of the protection materials 405. For example, the dielectric layers 407 are made of (silicon) nitride, and the protection materials 405 are made of (silicon) oxide, or vice versa.

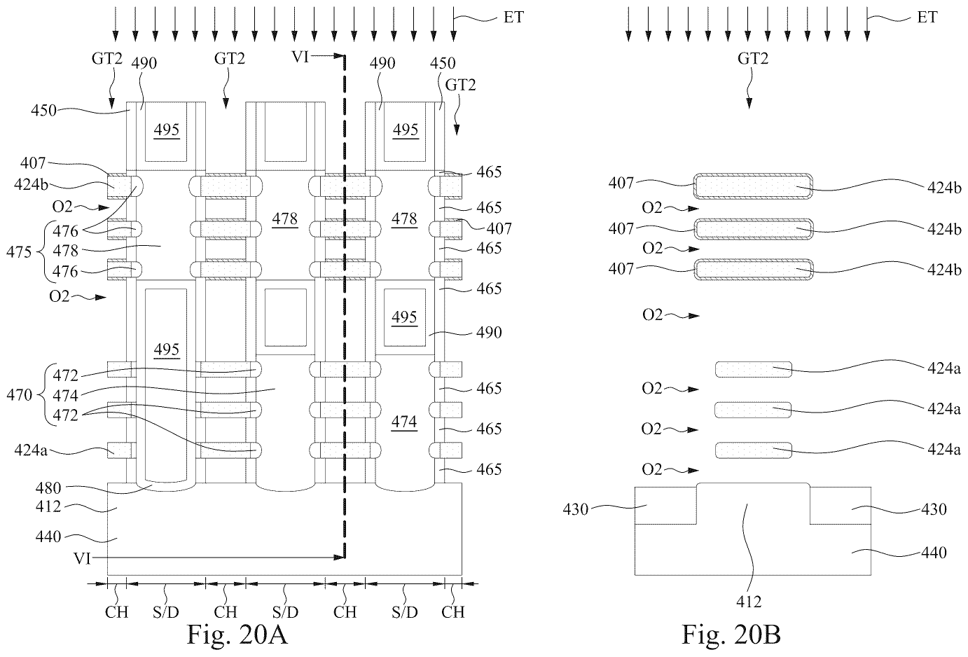

Reference is made to FIGS. 20A and 20B, where FIG. 20B is a cross-sectional view taken along line VI-VI of FIG. 20A. A selective etching process is performed to remove the protection materials 405 (see FIGS. 19A and 19B) to expose the semiconductor layers 424a. As mentioned above, the protection materials 405 and the dielectric layers 407 are made of different materials. As such, the selective etching process etches the protection materials 405 at a rate faster than it etches the dielectric layers 407. Therefore, the protection materials 405 are removed to expose the semiconductor layers 424a, and the dielectric layers 407 still cover the semiconductor layers 424b.

Another selective etching process ET is performed to trim the semiconductor layers 424a. Specifically, the selective etching process ET etches the semiconductor layers 424a at a rate faster than it etches the dielectric layers 407. As such, as shown in FIG. 20B, side portions of the semiconductor layers 424a are removed, and the width of the semiconductor layers 424a is reduced while the semiconductor layers 424b remain the same width. In some embodiments, the semiconductor layers 124a are etched or trimmed by using an etching process by using, for example, HF and Cl₂ as etching gases. In some embodiments, a time duration of the etching process is in a range of about 30 seconds to about 40 seconds. If the time duration is longer than about 40 seconds, the width reduction of the semiconductor layers 124a may be huge; if the time duration is less than about 30 seconds, the width reduction of the semiconductor layers 124a may be not enough.

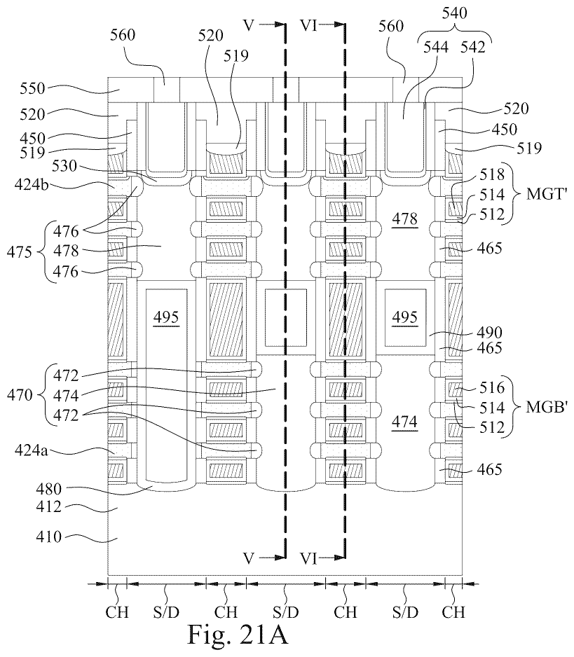

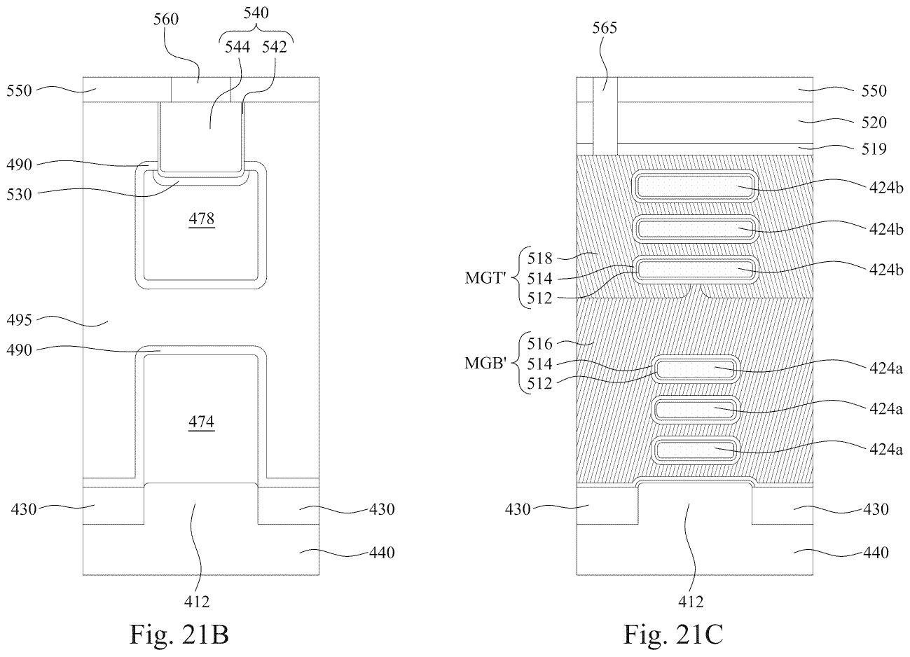

Reference is made to FIGS. 21A-21C, where FIG. 21B is a cross-sectional view taken along line V-V of FIG. 21A, and FIG. 21C is a cross-sectional view taken along line VI-VI of FIG. 21A. After the etching process ET shown in FIGS. 20A and 20B, the dielectric layers 407 are removed. The structure then undergoes the processes similar to the processes shown in FIGS. 9A-10C. Specifically, bottom (metal) gate structures MGB′ and top (metal) gate structures MGT′ are formed in the gate trenches GT2 and the openings O2. Materials, configurations, dimensions, processes and/or operations regarding the bottom gate structures MGB′ are similar to or the same as the bottom gate structures MGB of FIGS. 9A and 9B, and materials, configurations, dimensions, processes and/or operations regarding the top gate structures MGT′ are similar to or the same as the top gate structures MGT of FIGS. 9A and 9B. The bottom gate structures MGB′ includes interfacial layers 512, high-k gate dielectric layers 514, and a work function metal layer 516, and the top gate structures MGT′ includes the interfacial layers 512, the high-k gate dielectric layers 514, and a work function metal layer 518.

An etching back process is performed to etch back the top gate structures MGT′ and the gate spacers 450. Metal caps 519 are optionally formed respectively atop the top gate structures MGT′. Materials, configurations, dimensions, processes and/or operations regarding the metal caps 519 are similar to or the same as the metal caps 219 of FIGS. 10A-10C. Next, dielectric caps 520 are optionally deposited over the substrate 410. Materials, configurations, dimensions, processes and/or operations regarding the dielectric caps 520 are similar to or the same as the dielectric caps 220 of FIGS. 10A-10C.

Subsequently, openings are formed in the ILD layer 495. The opening exposes the top source/drain epitaxial structures 475. Front-side metal alloy layers 530 are then respectively formed above the top source/drain epitaxial structures 475. Materials, configurations, dimensions, processes and/or operations regarding the front-side metal alloy layers 530 are similar to or the same as the front-side metal alloy layers 230 of FIGS. 10A-10C.

Front-side source/drain contacts 540 are then respectively formed in the openings and on the front-side metal alloy layers 530. Each of the front-side source/drain contacts 540 includes a barrier layer 542 and filling materials 544. Materials, configurations, dimensions, processes and/or operations regarding the front-side source/drain contacts 540 are similar to or the same as the front-side source/drain contacts 240 of FIGS. 10A-10C.

An ILD layer 550 is then formed over the substrate 410. Materials, configurations, dimensions, processes and/or operations regarding the ILD layer 550 are similar to or the same as the ILD layer 250 of FIGS. 10A-10C. Source/drain vias 560 and at least one gate via 565 are then formed in the ILD layer 550. Materials, configurations, dimensions, processes and/or operations regarding the source/drain vias 560 and the gate via 565 are similar to or the same as the source/drain vias 260 and the gate via 265 of FIGS. 10A-10C.

Reference is made to FIGS. 22A-22C, where FIG. 22B is a cross-sectional view taken along line V-V of FIG. 22A, and FIG. 22C is a cross-sectional view taken along line VI-VI of FIG. 22A. The structure illustrated in FIGS. 21A-21C is “flipped” upside down, and the substrate 410 (see FIGS. 21A-21C) is thinned to expose the isolation structures 430 and the base portion 412 (see FIGS. 21A-21C). The base portion 412 of the substrate 410 are then patterned to form openings extending through the base portion 412 by using one or more etching process(es). After the one or more etching process(es), the openings expose portions of the bottom source/drain epitaxial structures 470. Backside metal alloy layers 570 are then formed in the openings and cover the bottom source/drain epitaxial structures 470. Materials, configurations, dimensions, processes and/or operations regarding the backside metal alloy layers 570 are similar to or the same as the backside metal alloy layers 270 of FIGS. 11A-11C.

Backside source/drain contacts 580 are then respectively formed in the openings and on the backside metal alloy layers 570. Each of the backside source/drain contacts 580 includes a barrier layer 582 and filling materials 584. Materials, configurations, dimensions, processes and/or operations regarding the backside source/drain contacts 580 are similar to or the same as the backside source/drain contacts 280 of FIGS. 11A-11C.

The base portion 412 and the isolation structures 430 are then removed. A backside etch stop layer 590 is conformally formed to cover the backside of the bottom gate structures MGB′ and the bottom source/drain epitaxial structures 470. Materials, configurations, dimensions, processes and/or operations regarding the backside etch stop layer 590 are similar to or the same as the backside etch stop layer 290 of FIGS. 11A-11C. A backside ILD layer 595 is then formed on the backside etch stop layer 590 and surrounds the backside source/drain contacts 580. Materials, configurations, dimensions, processes and/or operations regarding the backside ILD layer 595 are similar to or the same as the backside ILD layer 295 of FIGS. 11A-11C.

As such, the semiconductor device 400a is formed. As shown in FIGS. 22A-22C, the semiconductor device 400a includes a bottom (nanostructure) transistor BT′ and top (nanostructure) transistors TT1′ and TT2′. The top transistor TT1′ and the bottom transistor BT′ form a CFET. The top transistor TT1′ is directly over the bottom transistor BT′, and the top transistor TT2′ is over the bottom transistor BT′ and shares a top source/drain epitaxial structure 475 with the top transistor TT1′.

In some embodiments, the semiconductor device 400a is a static random access memory (SRAM) device. In some embodiments, the bottom transistor BT′ is a pull-up transistor (PU1 or PU2), the top transistor TT1′ is a pull-down transistor (PD1 or PD2), and the top transistor TT2′ is a pass gate transistor (PG1 or PG2).

The bottom transistor BT′ includes the channel structures 424a, the bottom source/drain epitaxial structures 470 on opposite sides of the channel structures 424a and connected to the channel structures 424a, and the bottom gate structure MGB′ wrapping around the channel structures 424a. Each of the top transistors TT1′ and TT2′ includes the channel structures 424b, the top source/drain epitaxial structures 475 on opposite sides of the channel structures 424b and connected to the channel structures 424b, and the top gate structure MGT′ wrapping around the channel structures 424b. The bottom transistor BT′ is a P-type transistor, and the top transistors TT1′ and TT2′ are N-type transistors, or vice versa.

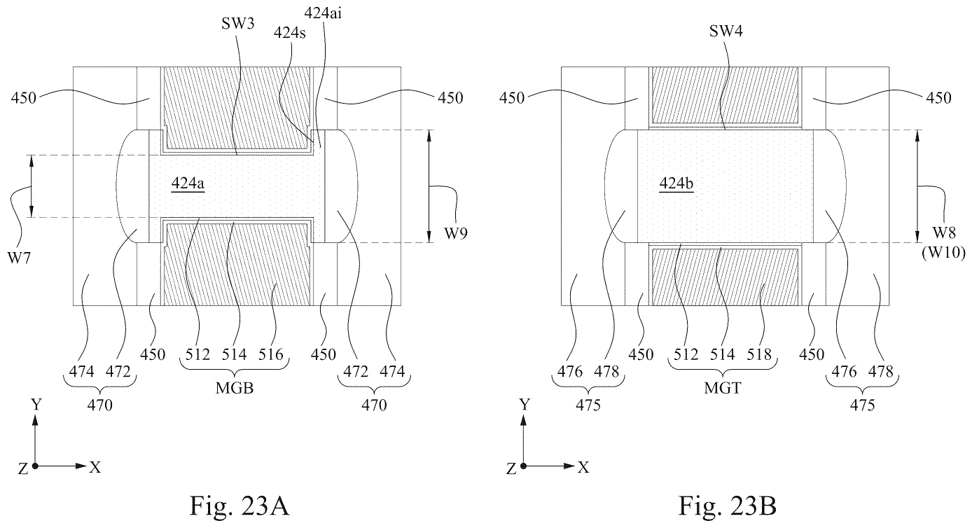

FIG. 23A is a cross-sectional view taken along line A′-A′ in FIG. 22C, and FIG. 23B is a cross-sectional view taken along line B′-B′ in FIG. 22C. In FIG. 23A, the channel structures 424a are wrapped by the bottom gate structure MGB′, and interconnect semiconductor portions 424ai of the channel structure are directly between the channel structure 424a and the bottom source/drain epitaxial structures 470 and are in contact with the bottom source/drain epitaxial structures 470. A minimum width W8 of the channel structure 424b in the Y direction is greater than a width W7 of the channel structure 424a in the Y direction. In some embodiments, a ratio of the width W7 to the minimum width W8 is in a range of about ¼ to about ⅓. However, a width W9 of the interconnect semiconductor portion 424ai in the Y direction is substantially equal to a maximum width W10 of the channel structure 424b in the Y direction. Further, the width W9 of the interconnect semiconductor portion 424ai in the Y direction is greater than the width W7 of the channel structure 424a in the Y direction. The bottom gate structure MGB′ is in contact with inner sidewalls 424s of the interconnect semiconductor portions 424ai. Therefore, a contact area (and thus the channel effective width) between the top gate structure MGT′ and the channel structures 424b is greater than a contact area (and thus the channel effective width) between the bottom gate structure MGB′ and the channel structures 424a. Such configuration improves the device performance.

Specifically, take an SRAM device as an example, the decreasing of the channel effective width in the bottom transistor BT′ improves the overpowered issues occurred in the transistor PU1 (PU2) since the channel width W7 of the bottom transistor BT′ is less than the channel width W8 of the top transistors TT1′ and TT2′. The smaller channel effective width of the bottom transistor BT′ also improves write margin of the SRAM device. On the other hand, the wider channels of the top transistors TT1′ and TT2′ improves the SRAM performance boost. The increasing of the channel effective width also increases the saturated current (Idsat) of the transistors TT1′ and TT2′ (i.e., the transistors PD and PG in this case), the SRAM cell Vccmin is also improved.

In some embodiments, the formation of the bottom gate structures MGB′ and the top gate structures MGT′ includes complex processes, such as repeated deposition and etching process cycles of dummy materials and/or work function metal layers. During the etching process, the etching gases may flow downward to the spacing between the semiconductor layers 424a to remove residues or dummy materials. For the semiconductor device 400a, after the channel structures 424a are trimmed as shown in FIG. 20B, the spacing in the gate trenches GT2 near the channel structures 424a is enlarged. The enlarged gate trenches GT2 are beneficial to the process gases (e.g., the etching or ashing gases) flowing downward to the bottom of the gate trenches GT2. Therefore, the CFET device process can be improved, and the CFET SRAM yield is also improved.

As shown in FIGS. 22C, 23A, and 23B, an outer sidewall SW3 of the channel structure 424a is misaligned with an outer sidewall SW4 of the channel structure 424b. Further, as shown in FIGS. 22A and 22B, a (maximum) width W11 of (the second epitaxial portions 474 of) the bottom source/drain epitaxial structure 470 is substantially equal to a (maximum) width W12 of (the second epitaxial portions 478 of) the top source/drain epitaxial structure 475. Further, in FIG. 22A, the channel structure 424a and the channel structure 424b have substantially the same width W13 in a direction from one of the bottom source/drain epitaxial structures 470 to another one of the bottom source/drain epitaxial structures 470 (i.e., the X direction in this case).

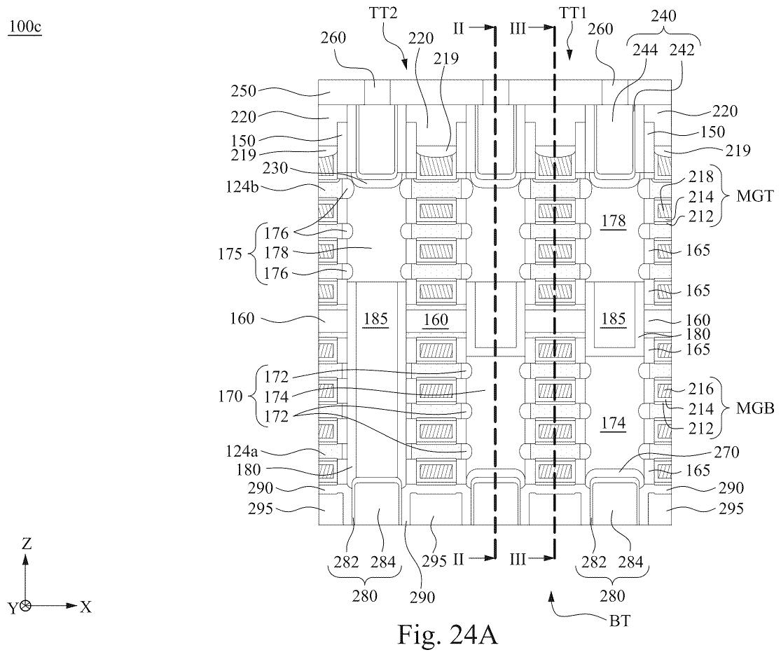

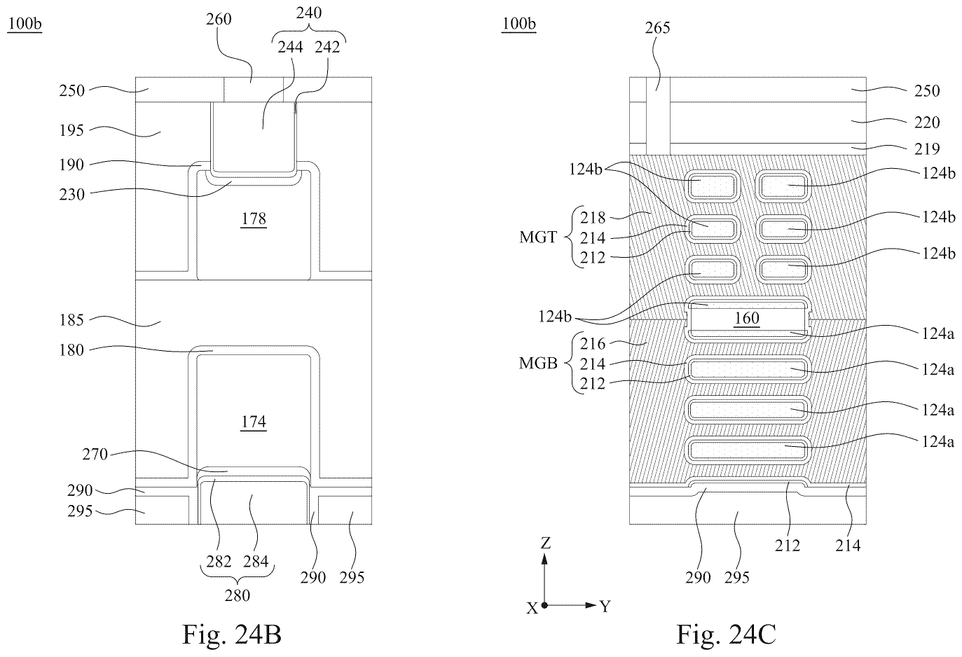

FIGS. 24A-24C are cross-sectional views of an integrated circuit structure (or a semiconductor device) 100b in accordance with some embodiments of the present disclosure, where FIG. 24B is a cross-sectional view taken along line II-II of FIG. 24A, and FIG. 24C is a cross-sectional view taken along line III-III of FIG. 24A. The difference between the semiconductor device 100b in FIGS. 24A-24C and the semiconductor device 100a in FIGS. 11A-11C pertains to the configuration of CESL and ILD layers. In some embodiments as shown in FIGS. 24A and 24B, prior to forming the top source/drain epitaxial structure 175, a CESL 180 and an ILD layer 185 are sequentially formed in the recesses R1 (see FIG. 4). The CESL 180 and an ILD layer 185 are then etched back to expose the semiconductor layers 124b. Subsequently, the top source/drain epitaxial structure 175 are formed in the recesses R1, and the CESL 190 and the ILD layer 195 are formed to cover the top source/drain epitaxial structure 175 and the ILD layer 185. Materials, configurations, dimensions, processes and/or operations regarding the CESL 180 are similar to or the same as the CESL 190 of FIG. 5A. Materials, configurations, dimensions, processes and/or operations regarding the ILD layer 185 are similar to or the same as the ILD layer 195 of FIG. 5A. Other relevant structural and manufacturing details of the semiconductor device 100b are substantially the same or similar to the semiconductor device 100a of FIGS. 11A-11C, and, therefore, a description in this regard will not be repeated hereinafter.

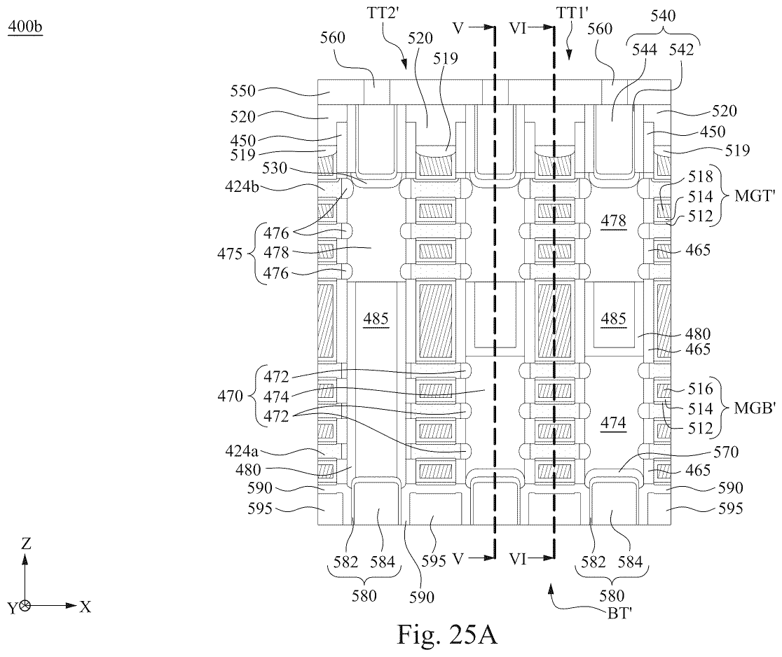

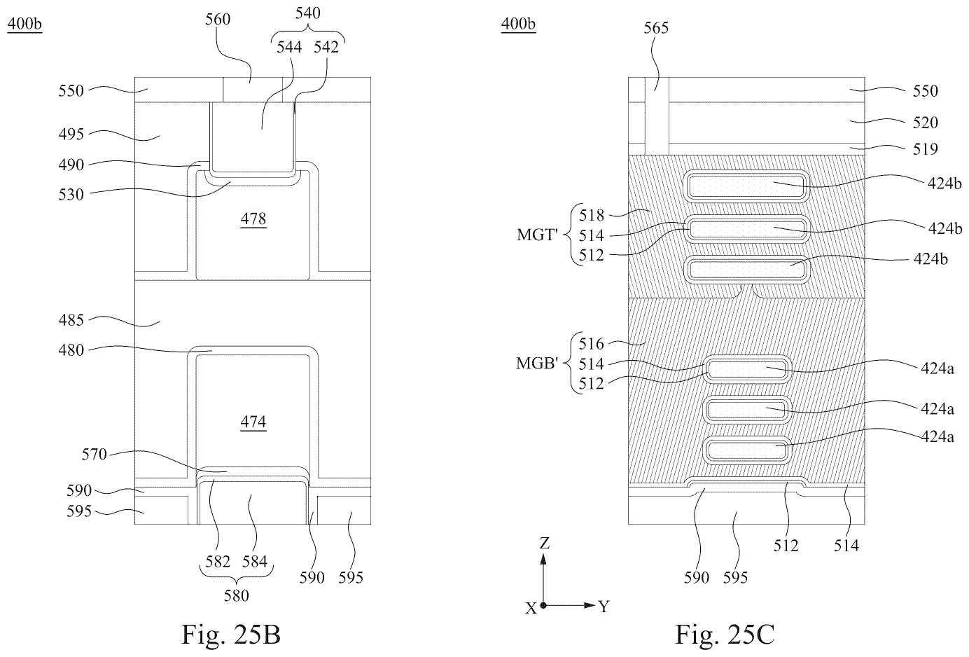

FIGS. 25A-25C are cross-sectional views of an integrated circuit structure (or a semiconductor device) 400b in accordance with some embodiments of the present disclosure, where FIG. 25B is a cross-sectional view taken along line V-V of FIG. 25A, and FIG. 25C is a cross-sectional view taken along line VI-VI of FIG. 25A. The difference between the semiconductor device 400b in FIGS. 25A-25C and the semiconductor device 400a in FIGS. 22A-22C pertains to the configuration of CESL and ILD layers. In some embodiments as shown in FIGS. 25A and 25B, prior to forming the top source/drain epitaxial structure 475, a CESL 480 and an ILD layer 485 are sequentially formed in the recesses R2 (see FIG. 15). The CESL 480 and an ILD layer 485 are then etched back to expose the semiconductor layers 424b. Subsequently, the top source/drain epitaxial structure 475 are formed in the recesses R2, and the CESL 490 and the ILD layer 495 are formed to cover the top source/drain epitaxial structure 475 and the ILD layer 485. Materials, configurations, dimensions, processes and/or operations regarding the CESL 480 are similar to or the same as the CESL 490 of FIG. 16A. Materials, configurations, dimensions, processes and/or operations regarding the ILD layer 485 are similar to or the same as the ILD layer 495 of FIG. 16A. Other relevant structural and manufacturing details of the semiconductor device 400b are substantially the same or similar to the semiconductor device 400a of FIGS. 22A-22C, and, therefore, a description in this regard will not be repeated hereinafter.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the channel effective width difference between the top transistor and the bottom transistor improves the device performance. The increasing of the channel number of the top transistor also improves the current crowding issues. Further, the shrinking of the channel width of the bottom transistor enlarges the gate trench spacing, benefiting to the process gases downward flowing to the bottom of the gate trench. Thus, the device yield is also improved.

According to some embodiments, a device includes a bottom transistor and a top transistor over the bottom transistor to form a complementary FET device. The top transistor includes a first channel layer, a second channel layer, a top gate structure, and top source/drain epitaxial structures. The first channel layer and the second channel layer are at a same level and extend in a first direction. The top gate structure wraps around the first channel layer and the second channel layer. The first channel layer and the second channel layer are arranged in a second direction substantially perpendicular to the first direction. The top source/drain epitaxial structures are connected to the first channel layer and the second channel layer.

According to some embodiments, a device includes a bottom transistor and a top transistor over the bottom transistor to form a complementary FET device. The bottom transistor includes a first channel layer, a bottom gate structure, and bottom source/drain epitaxial structures. The first channel layer extends in a first direction. The bottom gate structure wraps around the first channel layer. The bottom source/drain epitaxial structures are on opposite sides of the first channel layer. The top transistor includes a second channel layer, a top gate structure, and top source/drain epitaxial structures. The top gate structure wraps around the second channel layer. The top source/drain epitaxial structures are on opposite sides of the second channel layer. A width of the second channel layer in a second direction substantially perpendicular to the first direction is greater than a width of the first channel layer in the second direction in a top view.

According to some embodiments, a method includes forming a fin structure over a substrate, the fin structure including a first semiconductor layer, a sacrificial layer, and a second semiconductor layer from bottom to top. A dummy gate structure and gate spacers are formed over the substrate and across the fin structure. A recess is formed in the fin structure by using the dummy gate structure and the gate spacers as an etch mask. Bottom source/drain epitaxial structures are grown in the recess of the fin structure to be connected to the first semiconductor layer. Top source/drain epitaxial structures are grown in the recess of the fin structure to be connected to the second semiconductor layer. The dummy gate structure and the sacrificial layer are removed to form a gate trench between the gate spacers. A slit is formed in the second semiconductor layer. A bottom gate structure is formed in the gate trench to wrap around the first semiconductor layer and a top gate structure is formed in the gate trench to wrap around the second semiconductor layer. A portion of the top gate structure is in the slit of the second semiconductor layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
a bottom transistor; and
a top transistor over the bottom transistor to form a complementary FET device, the top transistor comprising:
a first channel layer and a second channel layer at a same level and extending in a first direction;
a top gate structure wrapping around the first channel layer and the second channel layer, wherein the first channel layer and the second channel layer are arranged in a second direction substantially perpendicular to the first direction; and
top source/drain epitaxial structures connected to the first channel layer and the second channel layer.

2. The device of claim 1, wherein a portion of the top gate structure is between the first channel layer and the second channel layer.

3. The device of claim 1, wherein the top transistor further comprises:
interconnect semiconductor portions on opposite sides of the first channel layer and the second channel layer, and each of the interconnect semiconductor portions is directly between the first channel layer and one of the top source/drain epitaxial structures.

4. The device of claim 3, wherein the interconnect semiconductor portions, the first channel layer, and the second channel layer forms a closed loop in a top view.

5. The device of claim 3, wherein a width of each of the interconnect semiconductor portions is greater than a width of the first channel layer.

6. The device of claim 1, wherein the bottom transistor comprises:
a third channel layer under the top transistor;
a bottom gate structure wrapping around the third channel layer; and
bottom source/drain epitaxial structures connected to the third channel layer, wherein a width of the third channel layer is greater than a width of the first channel layer.

7. The device of claim 6, wherein an outer sidewall of the third channel layer is substantially aligned with an outer sidewall of the first channel layer.

8. The device of claim 6, wherein a width of each of the bottom source/drain epitaxial structures is substantially equal to a width of each of the top source/drain epitaxial structures.

9. The device of claim 1, wherein a channel effective width of the top transistor is greater than a channel effective width of the bottom transistor.

10. A device comprising:
a bottom transistor comprising:
a first channel layer extending in a first direction;
a bottom gate structure wrapping around the first channel layer; and
bottom source/drain epitaxial structures on opposite sides of the first channel layer; and
a top transistor over the bottom transistor to form a complementary FET device, the top transistor comprising:
a second channel layer;
a top gate structure wrapping around the second channel layer; and
top source/drain epitaxial structures on opposite sides of the second channel layer, wherein a width of the second channel layer in a second direction substantially perpendicular to the first direction is greater than a width of the first channel layer in the second direction in a top view.

11. The device of claim 10, wherein the bottom transistor further comprises:
an interconnect semiconductor portion between the first channel layer and one of the bottom source/drain epitaxial structures.

12. The device of claim 11, wherein a width of the interconnect semiconductor portion in the second direction is greater than the width of the first channel layer in the second direction.

13. The device of claim 11, wherein a width of the interconnect semiconductor portion in the second direction is substantially equal to the width of the second channel layer in the second direction.

14. The device of claim 11, wherein the bottom gate structure is in contact with an inner sidewall of the interconnect semiconductor portion.

15. The device of claim 10, wherein the first channel layer and the second channel layer have substantially the same width in a direction from one of the bottom source/drain epitaxial structures to another one of the bottom source/drain epitaxial structures.

16. The device of claim 10, wherein a ratio of the width of the first channel layer to the width of the second channel layer is in a range of about ¼ to about ⅓.

17. The device of claim 10, wherein a width of each of the bottom source/drain epitaxial structures is substantially equal to a width of each of the top source/drain epitaxial structures.

18. The device of claim 10, wherein the bottom transistor is a pull-up transistor of an SRAM device, and the top transistor is a pull-down transistor of the SRAM device.

19. A method comprising:
forming a fin structure over a substrate, the fin structure comprising a first semiconductor layer, a sacrificial layer, and a second semiconductor layer from bottom to top;
forming a dummy gate structure and gate spacers over the substrate and across the fin structure;
forming a recess in the fin structure by using the dummy gate structure and the gate spacers as an etch mask;
growing bottom source/drain epitaxial structures in the recess of the fin structure to be connected to the first semiconductor layer;
growing top source/drain epitaxial structures in the recess of the fin structure to be connected to the second semiconductor layer;
removing the dummy gate structure and the sacrificial layer to form a gate trench between the gate spacers;
forming a slit in the second semiconductor layer; and
forming a bottom gate structure in the gate trench to wrap around the first semiconductor layer and a top gate structure in the gate trench to wrap around the second semiconductor layer, wherein a portion of the top gate structure is in the slit of the second semiconductor layer.

20. The method of claim 19, wherein forming the slit in the second semiconductor layer comprises:
forming a protection material in the gate trench to cover the first semiconductor layer but expose the second semiconductor layer;
etching the second semiconductor layer to form the slit in the second semiconductor layer; and
removing the protection material to expose the first semiconductor layer.
